(19) United States
(12) Patent Application Publication
(10) Pub. No.: US 2025/0253229 A1
(43) Pub. Date: Aug. 7, 2025

(54) CIRCUIT BOARD AND SEMICONDUCTOR PACKAGE COMPRISING SAME

(71) Applicant: LG INNOTEK CO., LTD., Seoul (KR)

(72) Inventors: Kee Han LEE, Seoul (KR); SANG IL KIM, Seoul (KR); Se Woong NA, Seoul (KR)

(73) Assignee: LG INNOTEK CO., LTD., Seoul (KR)

(21) Appl. No.: 18/856,537

(22) PCT Filed: Apr. 11, 2023
(86) PCT No.: PCT/KR2023/004859

§ 371 Date: Oct. 11, 2024

(30) Foreign Application Priority Data
Apr. 11, 2022 (KR) 10-2022-0044764

(51) Int. Cl. H01L 23/498; H01L 23/538; H05K 1/11

(52) U.S. Cl. CPC H01L 23/49894; H01L 23/5386; H05K 1/111

(57) ABSTRACT

A circuit board according to an embodiment includes an insulating layer; a circuit layer disposed on the insulating layer; and a protective layer disposed on the insulating layer, wherein the circuit layer includes a first-first pad and a first-second pad spaced apart from each other in a first horizontal direction, wherein the protective layer includes: a first protective pattern disposed between the first-first pad and the first-second pad and surrounding at least a portion of a side surface of the first-first pad and a side surface of the first-second pad; and a second protective pattern disposed surrounding the first protective pattern, an upper surface of the first protective pattern is positioned lower than an upper surface of the first-first pad and an upper surface of the first-second pad, an upper surface of the second protective pattern is positioned higher than the upper surfaces of the first-first pad and the first-second pad, and each of the first-first pad and the first-second pad has different widths in the first horizontal direction and in a second horizontal direction perpendicular to the first horizontal direction.

### TECHNICAL FIELD

The embodiment relates to a circuit board and a semiconductor package including the same.

### BACKGROUND ART

In general, a printed circuit board (PCB) is a laminated structure in which insulating layers and conductor layers are alternately laminated, and the conductor layers can be formed into a circuit pattern by patterning.

The printed circuit board is equipped with a solder resist (SR) that protects a circuit pattern formed at an outermost side of the laminated structure, prevents oxidation of the conductor layer, and also acts as an insulator when electrically connecting to a chip or other substrate mounted on the printed circuit board.

A typical solder resist has an opening region (SRO: Solder Resist Opening) that is an electrical connection passage by combining connecting means such as solder or bumps, and a number of solder resist opening regions is required to increase as an I/O (Input/Output) performance is improved due to a high performance and high density of the printed circuit board, and accordingly, a small bump pitch of the opening region is required. At this time, the bump pitch of the solder resist opening region means a distance between centers of adjacent opening regions.

Meanwhile, the opening region (SRO) of the solder resist includes a SMD (Solder Mask Defined type) type and a NSMD (Non-Solder Mask Defined Type) type.

The SMD type is characterized in that a width of the opening region (SRO) is smaller than a width of a pad exposed through the opening region (SRO), and thus, at least a part of an upper surface of the pad in the SMD type is covered by the solder resist.

In addition, the NSMD type is characterized in that a width of the opening region (SRO) is greater than a width of the pad exposed through the opening region (SRO), and accordingly, the solder resist in the NSMD type is disposed at a certain distance from the pad, and thus has a structure in which both an upper surface and a side surface of the pad are exposed.

However, in a case of the SMD type, after the semiconductor package is combined with a main board, there is a problem that a solder ball is separated from the pad exposed through the opening region (SRO) during a solder ball joint reliability test for a bonding strength of the solder ball. In addition, in a case of the NSMD type, there is a problem that the pad on which the solder ball is disposed is separated from the circuit board. Accordingly, conventionally, the SMD type and the NSMD type are appropriately combined and applied to one circuit board.

At this time, the conventional circuit board provides a space in which a component such as a multi-layered ceramic capacitor (MLCC) is mounted. At this time, the solder resist in the space where the multi-layered ceramic capacitor is disposed in the conventional circuit board has an SMD type. Accordingly, the semiconductor package in which the multi-layered ceramic capacitor is mounted on the conventional circuit board has a problem in that an overall thickness of the semiconductor package increases by a thickness of the solder resist.

To solve this, the solder resist is not disposed in a space where the multi-layered ceramic capacitor is disposed in the conventional circuit board. In addition, an adhesive member such as the solder ball has a structure that extends along a side surface of the pad. Accordingly, the structure in which the solder resist is not disposed has a short circuit problem in which the adhesive member disposed on each adjacent pad are interconnected.

(Patent Document 1) KR 10-2013-0046726 A

(Patent Document 2) KR 10-1877963 B

### DISCLOSURE

### Technical Problem

The embodiment provides a circuit board capable of being slimmed down and a semiconductor package including the same.

In addition, the embodiment provides a circuit board capable of reducing a spacing between adjacent pads and a semiconductor package including the same.

In addition, the embodiment provides a circuit board capable of resolving a short circuit problem between adhesive members disposed on pads and a semiconductor package including the same.

In addition, the embodiment provides a circuit board having improved physical reliability and electrical reliability and a semiconductor package including the same.

In addition, the embodiment provides a circuit board capable of resolving a problem of an adhesive member penetrating between an insulating layer and a pad and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; a circuit layer disposed on the insulating layer; and a protective layer disposed on the insulating layer, wherein the circuit layer includes a first-first pad and a first-second pad spaced apart from each other in a first horizontal direction, wherein the protective layer includes: a first protective pattern disposed between the first-first pad and the first-second pad and surrounding at least a portion of a side surface of the first-first pad and a side surface of the first-second pad; and a second protective pattern disposed surrounding the first protective pattern, an upper surface of the first protective pattern is positioned lower than an upper surface of the first-first pad and an upper surface of the first-second pad, an upper surface of the second protective pattern is positioned higher than the upper surfaces of the first-first pad and the first-second pad, and each of the first-first pad and the first-second pad has different widths in the first horizontal direction and in a second horizontal direction perpendicular to the first horizontal direction.

In addition, a thickness of the first protective pattern satisfies a range of 40% to 90% of a thickness of at least one of the first-first pad and the first-second pad.

In addition, a thickness of at least one of the first-first pad and the first-second pad satisfies a range of 10 μm to 25 μm, and a thickness of the first protective pattern satisfies a range of 3 μm to 21 μm.

In addition, a vertical distance between the upper surface of at least one of the first-first pad and the first-second pad and the upper surface of the first protective pattern satisfies a range of 3 μm to 10 μm.

In addition, at least one of the upper surfaces of the first-first pad and the first-second pad includes a curved surface, and the vertical distance is a vertical distance from an uppermost surface of the at least one of the first-first pad and the first-second pad to an uppermost surface of the first protective pattern.

In addition, the thickness of the second protective pattern satisfies a range of 17 μm to 45 μm.

In addition, the width of each of the first-first pad and the first-second pad in the second horizontal direction is in a range of 125% to 220% of the width of each of the first-first pad and the first-second pad in the first horizontal direction.

In addition, a spacing between the first-first pad and the first-second pad satisfies a range of 70% to 120% of the width of each of the first-first pad and the first-second pad in the first horizontal direction.

In addition, an inner wall of the second protective pattern is spaced apart from a side surface of at least one of the first-first pad and the first-second pad by a spacing of 15 μm to 23 μm.

In addition, the first protective pattern is provided to partially surround the side surfaces of the first-first pad and the first-second pad, and at least a portion of the second protective pattern is in contact with the side surface of the first-first pad or the side surface of the first-second pad.

In addition, the first-first pad includes a first-first side surface facing the first-second pad, and a first-second side surface excluding the first-first side surface, and the first-second pad includes a 2-1 side surface facing the first-first side surface, and a 2-2 side surface excluding the 2-1 side surface, and the second protective pattern is in direct contact with at least a portion of the first-second side surface of the first-first pad and the 2-2 side surface of the first-second pad.

In addition, the circuit layer further includes a second pad and a second trace, the second pad has a width in a range of 3 μm to 30 μm, and the second trace has a width in a range of 1 μm to 10 μm, and a spacing between the second pad and the second trace has a range of 1 μm to 10 μm.

In addition, the second pad is provided in multiple numbers, the second trace is provided in multiple numbers, the protective layer has a through hole that vertically overlaps the plurality of second pads, the plurality of second traces, and regions between the plurality of second pads and the plurality of second traces.

In addition, the second pad is provided in multiple numbers, the second trace is provided in multiple numbers, the protective layer further includes a third protective pattern provided between the plurality of second pads and the plurality of second traces, and the third protective pattern does not vertically overlap the second pad and the second trace.

In addition, an upper surface of the third protective pattern is positioned lower than an upper surfaces of each of the second pads and the second trace.

In addition, the circuit layer further includes a plurality of third pads and a plurality of third traces, a width of the third pads satisfies a range of 30 μm to 70 μm, a spacing between the third pads and the third traces satisfies a range of 10 μm to 40 μm.

In addition, the protective layer further includes a fourth protective pattern that has a width smaller than a width of the third pad and overlaps the third pad in a vertical direction.

### Advantageous Effects

The circuit board of the embodiment includes a first region in which a first semiconductor device is arranged.

In addition, the circuit board includes a first-first pad and a first-second pad. The first-first pad and the first-second pad are provided so as to overlap the first semiconductor device in a vertical direction. For example, the first-first pad and the first-second pad are provided in a first region of the circuit board. In addition, the embodiment includes a protective layer. The protective layer includes a first protective pattern disposed between the first-first pad and the first-second pad, and surrounding at least a portion of a side surface of the first-first pad and a side surface of the first-second pad. In addition, the protective layer includes a second protective pattern provided surrounding the first protective pattern.

The first protective pattern contacts at least a portion of a side surface of the first-first pad and the first-second pad without contacting upper surfaces of the first-first pad and the first-second pad. For example, an upper surface of the first protective pattern is positioned lower than the upper surfaces of the first-first pad and the first-second pad. Therefore, the embodiment can reduce a thickness and a width of a contact member to be disposed on the first-first pad and the first-second pad by using the first protective pattern.

For example, a first comparative example has a problem in that a thickness of the contact member increases due to an arrangement of the protective layer, and the second comparative example had a problem in that an degree of expansion of the contact member increased due to an non-arrangement of the protective layer, thereby increasing the width of the contact member.

In contrast, the embodiment can reduce the degree of expansion of the contact member and reduce the width of the contact member by using a combination of the first and second protective patterns. In addition, the embodiment provides only the first protective pattern in a region that vertically overlaps the first semiconductor device.

For example, the second protective pattern does not vertically overlap the first semiconductor device. Therefore, the embodiment can prevent a thickness of the contact member from increasing due to a height of the protective layer.

Accordingly, the embodiment can reduce a thickness of the semiconductor package, thereby achieving miniaturization. Furthermore, the embodiment can solve a problem of a circuit short between adjacent contact members by reducing the degree of expansion of the contact member. As a result, the embodiment can improve the electrical reliability and product reliability of the semiconductor package. Furthermore, the embodiment can solve the problem of a circuit short without increasing a spacing between the first-first pad and the first-second pad, thereby improving circuit integration.

In addition, the embodiment can solve a problem of an adhesive member penetrating between an insulating layer and a pad by using the first protective pattern, thereby further improving product reliability.

### DESCRIPTION OF DRAWINGS

FIG. 1 is a cross-sectional view of a semiconductor package according to a first comparative example.

FIG. 2 is a cross-sectional view of a semiconductor package according to a second comparative example.

FIG. 3 is a cross-sectional view showing an entire layer structure of a circuit board according to one embodiment.

FIG. 4 is a view showing a structure of a second region of a circuit board according to a first embodiment.

FIG. 5 is a view showing a structure of a second region of a circuit board according to a second embodiment.

FIG. 6 is a view showing a structure of a third region of a circuit board according to an embodiment.

FIG. 7a is a plan view of a first region of a circuit board according to a first embodiment.

FIG. 7b is a cross-sectional view taken along a C-C′ direction of FIG. 7a.

FIG. 7c is a cross-sectional view taken along a D-D′ direction of FIG. 7a.

FIG. 8 is a perspective view showing a semiconductor device mounted on a first region of a circuit board according to one embodiment.

FIG. 9 is a plan view of a first region of a circuit board according to a second embodiment.

FIG. 10a is a plan view of a first region of a circuit board according to a third embodiment.

FIG. 10b is a cross-sectional view taken along a E-E′ direction of FIG. 10a.

FIG. 10c is a cross-sectional view taken along a F-F′ direction of FIG. 10a.

FIG. 10d is a modified example of a structure of FIG. 10c.

FIG. 11a is a plan view of a first region of a circuit board according to a fourth embodiment.

FIG. 11b is a cross-sectional view taken along a G-G′ direction of FIG. 10a.

FIG. 12 is a cross-sectional view showing a semiconductor package according to an embodiment.

FIG. 13a is an enlarged view of a first semiconductor device arrangement region of FIG. 12 according to a first embodiment.

FIG. 13b is an enlarged view of a first semiconductor device arrangement region of FIG. 12 according to a second embodiment.

FIGS. 14 to 21 are cross-sectional views showing a process of manufacturing a circuit board according to an embodiment in order of processes.

### MODES OF THE INVENTION

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### Comparative Example

Before explaining the embodiment, a comparative example that is compared with the circuit board of the embodiment of the present invention will be explained.

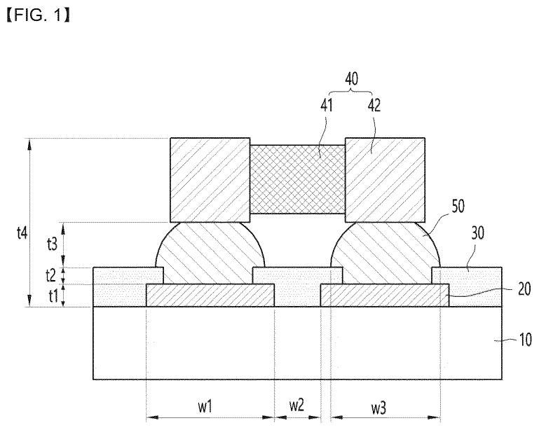

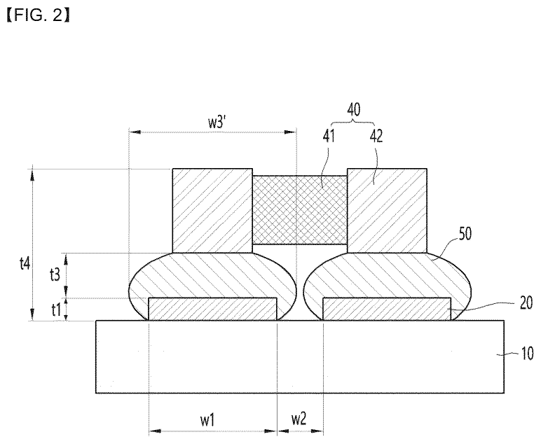

FIG. 1 is a cross-sectional view of a semiconductor package according to a first comparative example, and FIG. 2 is a cross-sectional view of a semiconductor package according to a second comparative example.

Referring to FIG. 1, a semiconductor package according to a first comparative example includes a circuit board and a device mounted on the circuit board.

The circuit board of the first comparative example includes an insulating layer 10, a circuit layer 20, and a protective layer 30.

The circuit layer 20 is disposed on an upper surface of the insulating layer 10. The circuit layer 20 may represent an outermost layer among a plurality of circuit layers disposed on the circuit board. For example, the circuit layer 20 represents a circuit layer of a region where a chip is mounted on the circuit board.

For example, the circuit layer 20 represents a pad on which a multi-layered ceramic capacitor is disposed.

The protective layer 30 is disposed on the insulating layer 10.

At this time, the protective layer 30 is disposed on the insulating layer 10 with a certain thickness. Specifically, the protective layer 30 is disposed on the insulating layer 10 with a thickness greater than a thickness of the circuit layer 20.

The protective layer 30 includes an opening (not shown) that overlaps an upper surface of the circuit layer 20 in a thickness direction. A planar area of the opening of the protective layer 30 is smaller than a planar area of the circuit layer 20. That is, the protective layer 30 is disposed to cover a part of the upper surface of the circuit layer 20. In addition, the protective layer 30 overlaps at least a part of the upper surface of the circuit layer 20 in the thickness direction, and thereby does not come into contact with at least a part of the upper surface of the circuit layer 20.

An adhesive member 50 is disposed in the opening of the protective layer 30. The adhesive member 50 may be a solder ball.

In addition, a device 40 can be mounted on the circuit layer 20 through the adhesive member 50. The device 40 has a structure in which a body 41 and terminals 42 are formed on both sides of the body 41. That is, the device 40 is a passive device. For example, the device 40 is a multi-layered ceramic capacitor.

At this time, in the first comparative example, the protective layer 30 in a region where the device 40 is mounted is disposed higher than an upper surface of the circuit layer 20. Accordingly, in the first comparative example, there is a problem in that an overall thickness of the semiconductor package increases by a protruding thickness of the protective layer 30.

That is, the circuit layer 20 includes a pad that is electrically connected to the device 40. The pad has a size corresponding to the terminal 42 of the device 40. For example, a width w1 of the pad in a first horizontal direction exceeds 140 μm. For example, the width w1 of the pad in the first horizontal direction exceeds 190 μm. For example, the width w1 of the pad in the first horizontal direction exceeds 300 μm. For example, the width w1 of the pad in the first horizontal direction exceeds 450 μm. The first horizontal direction means a separation direction of the plurality of terminals 42 of the device 40.

And, in the circuit board of the first comparative example, a spacing w2 between the plurality of pads connected to the device 40 exceeds 120 μm. For example, in the circuit board of the first comparative example, the spacing w2 between the plurality of pads connected to the device 40 exceeds 200 μm. For example, in the circuit board of the first comparative example, the spacing w2 between the plurality of pads connected to the device 40 exceeds 300 μm.

Meanwhile, a maximum width w3 of the adhesive member 50 in the first horizontal direction has a level similar to the width w1 of the pad. For example, the maximum width w3 of the first horizontal direction of the adhesive member 50 has a level of 80% to 105% of the width of the pad.

Meanwhile, a thickness t1 of the circuit layer 20 of the first comparative example has a range of 10 μm to 20 μm. In addition, in a total thickness of the protective layer 30, a thickness t2 of a portion protruding on the upper surface of the circuit layer 20 has a range of 7 μm to 20.

At this time, the adhesive member 50 is disposed with a certain thickness t3 from the upper surface of the protective layer 30. The thickness t3 is set based on a condition that allows the device 40 to be stably mounted on the circuit layer 20.

At this time, the thickness t3 in the first comparative example is set based on the upper surface of the protective layer 30, not the upper surface of the circuit layer 20. That is, when the thickness t3 is set based on the upper surface of the circuit layer 20, a problem may occur in which a part of the device 40 comes into contact with the upper surface of the protective layer 30 during a process of mounting the device 40. As a result, the device 40 may be mounted in a distorted state.

Accordingly, a thickness t4 from the upper surface of the insulating layer 10 to the upper surface of the device 40 in the first comparative example reflects not only the thickness t1 of the circuit layer 20 and the thickness t3 of the adhesive member 50, but also the thickness t2 of the protruding portion of the protective layer 30. Therefore, in the first comparative example, there is a problem in that the overall thickness in a structure in which the device 40 is mounted increases by the thickness t2 of the protruding portion of the protective layer 30.

Meanwhile, in a second comparative example in FIG. 2, in order to solve the problem of the first comparative example, the protective layer 30 is not disposed in a region where the device 40 is mounted.

At this time, the protective layer 30 may not be disposed in a region where the circuit layer 20 is disposed, and thus, the structure has no insulating member between the plurality of pads of the circuit layer 20. Accordingly, the second comparative example has a problem in that dendrites occur between the plurality of pads. For example, a circuit board on which a semiconductor device is mounted may have an electrical problem in that a voltage corresponding to a driving power of the semiconductor device is applied, and a metal forming the plurality of pads may grow into a dendrite shape due to the applied voltage, causing two adjacent pads to be short-circuited with each other, which means a short-circuit due to the occurrence of migration. For example, when a certain level of voltage is applied to the circuit layer, metal ions may grow into a dendrite shape from a positive polarity pattern toward a negative polarity pattern, and thus, a problem in that the plurality of pads are electrically short-circuited with each other may occur.

In addition, the second comparative example may reduce the thickness of the semiconductor package by the thickness t2 of the protruding portion of the protective layer 30 of the first comparative example. A thickness t4′ between the insulating layer 10 and the device 40 in the second comparative example may be smaller than the thickness t4 of the first comparative example by the thickness t2 of the protruding portion of the protective layer 30.

In addition, since the second comparative example has a structure in which the protective layer 30 does not exist, there is a problem in that a width of the adhesive member 50 becomes relatively great.

Specifically, the adhesive member 50 is disposed on the circuit layer 20. At this time, the adhesive member 50 is disposed on the circuit layer 20 and has a structure in which it is disposed along the surface of the metal circuit layer 20.

At this time, in the first comparative example, since the adhesive member 50 does not come into contact with the side surface of the circuit layer 20, the width w3 of the adhesive member 50 is similar to the width w1 of the pad of the circuit layer 20.

In contrast, the second comparative example has a structure in which a side surface of the circuit layer 20 is entirely exposed. Accordingly, the adhesive member 50 of the second comparative example is disposed to cover not only the upper surface of the circuit layer 20 but also the entire side surface.

That is, a width w3′ of the adhesive member 50 of the second comparative example is larger than the width of the pad of the circuit layer 20. Specifically, a width w3′ of the adhesive member 50 of the second comparative example exceeds 130% of the width of the pad. More specifically, the width w3′ of the adhesive member 50 of the second comparative example exceeds 140% of the width of the pad.

At this time, the device 40 includes two terminals 42. In addition, since the adhesive member 50 of the second comparative example has a structure in which it extends along the side surface of the circuit layer 20, there is a problem in that a spacing between two adhesive members in contact with the two terminals becomes narrower. In addition, the spacing between the two adhesive members becomes narrower as the thickness or width of the circuit layer 20 increases. Accordingly, a structure in which the protective layer 30 in the second comparative example is not disposed has a problem in that the spacing between the two contact members becomes narrower. Furthermore, the second comparative example has a problem in that a circuit short occurs between the two adhesive members depending on the degree of expansion of the adhesive member 50. In addition, the second comparative example makes the spacing w2 between the two pads larger than that of the first comparative example in order to solve the circuit short problem. Accordingly, the semiconductor package of the second comparative example can have a thickness smaller than that of the semiconductor package of the first comparative example. However, there is a problem that a size of the semiconductor package increases in the horizontal direction due to the problem of reduced circuit integration.

In addition, as the performance of electric/electronic products has been improved recently, technologies for mounting a larger number of elements on a limited-sized substrate have been studied, and accordingly, miniaturization of a width and a spacing of the circuit layer is required. However, in the case of the semiconductor packages of the first comparative example and the second comparative example, it is difficult to reduce the overall thickness, or there is a limit to reducing the spacing between the circuit layers due to the circuit short problem. In addition, the functions processed by application processors (APs) have been increasing in recent years, and accordingly, it has become difficult to implement them in a single chip. However, in comparative examples, there is difficulty in mounting two application processors (APs) or multiple passive devices with different functions in a limited space.

The embodiment is intended to solve the problems of these comparative examples by dividing the circuit board into multiple regions and having the protective layers in the multiple regions have different open structures. Accordingly, the embodiment can reduce a spacing between pads on which devices are mounted without increasing the overall thickness of the semiconductor package. Through this, the embodiment can improve the integration of the circuit board, thereby enabling mounting of multiple chips on a single circuit board. For example, the embodiment can provide a circuit board having a new structure capable of mounting multiple processor chips or memory chips with different functions on a single circuit board, and a semiconductor package including the same.

### Electronic Device

Before describing an embodiment, an electronic device including a semiconductor package of an embodiment will be briefly described. The electronic device includes a main board (not shown). The main board may be physically and/or electrically connected to various components. For example, the main board may be connected to a semiconductor package according to an embodiment. Various chips may be mounted on the semiconductor package. To explain broadly, memory chips such as volatile memory (e.g., DRAM), non-volatile memory (e.g., ROM), and flash memory, application processor chips such as a central processor (e.g., CPU), a graphics processor (e.g., GPU), an antenna chip, a digital signal processor, a cryptographic processor, a microprocessor, and a microcontroller, and logic chips such as analog-digital converters and ASICs (application-specific ICs), and passive devices can be mounted on the package substrate. In addition, the circuit board of the embodiment may also be used as a package substrate on which a memory chip or a logic chip is mounted.

Specifically, the semiconductor package of the embodiment may be equipped with at least one chip, and the chip may include at least one of a processor chip, a passive chip, and an active chip. Specifically, an electronic component such as a chip may be equipped in the semiconductor package. In addition, the chip may be either an active chip or a passive chip. The active chip means a chip that actively utilizes a nonlinear portion of a signal characteristic. In addition, the passive chip means a chip that does not utilize a nonlinear signal characteristic even though both linear and nonlinear signal characteristics exist. For example, the active chip may include a transistor, an IC semiconductor chip, and the like, and the passive chip may include a capacitor, a resistor, an inductor, and the like. The passive chip may increase a signal processing speed of a semiconductor chip, which is an active chip, or perform a filtering function, and the like. In addition, the chip may be a wireless communication chip that can be used for Wi-Fi or 5G communication.

Meanwhile, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package On Package), and SIP (System In Package), but is not limited thereto.

In this case, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### Embodiment

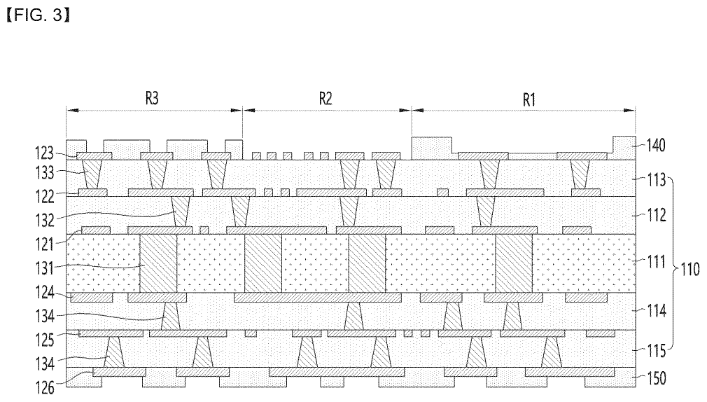

FIG. 3 is a cross-sectional view showing an entire layer structure of a circuit board according to an embodiment.

Referring to FIG. 3, the circuit board includes a plurality of insulating layers.

At this time, the circuit board may be a core board including a core layer. However, the present invention is not limited thereto, and the circuit board of the present invention may be a coreless board that does not include a core layer.

However, for the convenience of explanation, the circuit board of the present invention will be described as a core board including a core layer.

In addition, although the circuit board of the embodiment in the drawing is shown as having a five-layer structure based on a number of insulating layers, and the embodiment is not limited thereto. For example, the circuit board of the embodiment may have four or fewer layers based on a number of insulating layers, or alternatively, may have six or more layers.

Hereinafter, a circuit board having a five-layer insulating layer structure including a core layer will be described as an example of the embodiment.

The insulating layer 110 of the embodiment includes a first insulating layer 111. The first insulating layer 111 may be an insulating layer in which copper foils are laminated on both surfaces. Preferably, the first insulating layer 111 may be a copper clad laminate (CCL).

In particular, the copper clad laminate is a general substrate on which a circuit board is manufactured, and is a laminate structure in which copper foil is laminated on an insulating layer. The copper clad laminate may include a glass/epoxy copper clad laminate, a heat-resistant resin copper clad laminate, a paper/phenol copper clad laminate, a high-frequency copper clad laminate, a flexible copper clad laminate (e.g., a polyimide film), and a composite copper clad laminate, depending on an application. At this time, the first insulating layer 111 of the embodiment may use a glass/epoxy copper-clad laminate to manufacture a double-sided circuit board and a multilayer circuit board, but is not limited thereto.

The first insulating layer 111 may have a thickness in a range of 100 μm to 500 μm. Preferably, the first insulating layer 111 may have a thickness in a range of 120 μm to 480 μm. More preferably, the first insulating layer 111 may have a thickness in a range of 150 μm to 450 μm.

If a thickness of the first insulating layer 111 is less than 100 μm, the rigidity and warpage characteristics of the circuit board may deteriorate. In addition, if the thickness of the first insulating layer 111 exceeds 500 μm, a thickness of the circuit layer, a line width of the circuit layer, a spacing between the circuit layers, and a thickness of a through electrode disposed on or in the first insulating layer 110 may increase.

The insulating layer 110 may include a plurality of insulating layers laminated on upper and lower portions of the first insulating layer 111, respectively. For example, the insulating layer 110 may include a second insulating layer 112 disposed on an upper surface of the first insulating layer 111, a third insulating layer 113 disposed on an upper surface of the second insulating layer 112, a fourth insulating layer 114 disposed on a lower surface of the first insulating layer 111, and a fifth insulating layer 115 disposed on a lower surface of the fourth insulating layer 114.

The second to fifth insulating layers 115 may include a prepreg (PPG). The prepreg can be formed by impregnating a fiber layer in the form of a fabric sheet, such as a glass fabric woven with glass fiber yarn, with an epoxy resin, etc., and then performing heat pressing. However, the embodiment is not limited thereto, and the prepreg constituting the second to fifth insulating layers 115 may include a fiber layer in a form of a fabric sheet woven with carbon fiber yarn.

In addition, at least one of the second to fifth insulating layers 115 may be rigid or flexible. For example, at least one of the second to fifth insulating layers 115 may include RCC (Resin Coated Copper), ABF (Ajinomoto Build-up Film), FR-4, BT (Bismaleimide Triazine), PID (Photo Imageable Dielectric resin), BT, etc.

Each of the second to fifth insulating layers 115 may have a thickness in a range of 10 μm to 60 μm. Preferably, each of the second to fifth insulating layers 115 may have a thickness in a range of 12 μm to 50 μm. More preferably, each of the second to fifth insulating layers 115 may have a thickness in a range of 15 μm to 40 μm.

If a thickness of each of the second to fifth insulating layers 115 is less than 10 μm, the circuit layer included in the circuit board may not be stably protected. If the thickness of each of the second to fifth insulating layers 115 exceeds 60 μm, the thickness of the circuit board and the semiconductor package including the circuit board may increase. If the thickness of each of the second to fifth insulating layers 115 exceeds 60 μm, the thickness of the circuit layer and the thickness of the through electrode may increase correspondingly. In addition, if the thickness of the circuit layer and the thickness of the through electrode increase, signal transmission loss may increase.

The circuit board of the embodiment includes a circuit layer.

The circuit layer may be disposed on each surface of the insulating layer 110. For example, the circuit layer may include a first circuit layer 121 disposed on an upper surface of the first insulating layer 111, a second circuit layer 122 disposed on an upper surface of the second insulating layer 112, a third circuit layer 123 disposed on an upper surface of the third insulating layer 113, a fourth circuit layer 124 disposed on a lower surface of the first insulating layer 111, a fifth circuit layer 125 disposed on a lower surface of the fourth insulating layer 114, and a sixth circuit layer 126 disposed on a lower surface of the fifth insulating layer 115.

At least one of the first circuit layer 121, the second circuit layer 122, the third circuit layer 123, the fourth circuit layer 124, the fifth circuit layer 125, and the sixth circuit layer 126 may have a thickness of 10 μm to 25 μm. Preferably, at least one of the first circuit layer 121, the second circuit layer 122, the third circuit layer 123, the fourth circuit layer 124, the fifth circuit layer 125, and the sixth circuit layer 126 may have a thickness of 12 μm to 23 μm. More preferably, at least one of the first circuit layer 121, the second circuit layer 122, the third circuit layer 123, the fourth circuit layer 124, the fifth circuit layer 125, and the sixth circuit layer 126 may have a thickness of 15 μm to 20 μm.

The first circuit layer 121, the second circuit layer 122, the third circuit layer 123, the fourth circuit layer 124, the fifth circuit layer 125, and the sixth circuit layer 126 may include a conductive material. For example, the first circuit layer 121, the second circuit layer 122, the third circuit layer 123, the fourth circuit layer 124, the fifth circuit layer 125, and the sixth circuit layer 126 may include at least one metal material selected from gold (Au), silver (Ag), platinum (Pt), titanium (Ti), tin (Sn), copper (Cu), and zinc (Zn). Preferably, the first circuit layer 121, the second circuit layer 122, the third circuit layer 123, the fourth circuit layer 124, the fifth circuit layer 125, and the sixth circuit layer 126 can be formed of copper (Cu) that has high electrical conductivity and is relatively inexpensive.

The first circuit layer 121, the second circuit layer 122, the third circuit layer 123, the fourth circuit layer 124, the fifth circuit layer 125, and the sixth circuit layer 126 can be formed by a conventional circuit board manufacturing process, such as an additive process, a subtractive process, a modified semi-additive process (MSAP), and a semi-additive process (SAP), and a detailed description thereof is omitted here.

The circuit board includes a through electrode. For example, the circuit board includes a through electrode that passes through an insulating layer and electrically connects circuit layers disposed on different layers.

For example, the through electrode includes a first through electrode 131 penetrating the first insulating layer 111. The first through electrode 131 can electrically connect between the first circuit layer 121 and the fourth circuit layer 124.

In addition, the through electrode includes a second through electrode 132 penetrating the second insulating layer 112. The second through electrode 132 can electrically connect between the first circuit layer 121 and the second circuit layer 122.

In addition, the through electrode includes a third through electrode 133 penetrating the third insulating layer 113. The third through electrode 133 can electrically connect between the second circuit layer 122 and the third circuit layer 123.

In addition, the through electrode includes a fourth through electrode 134 penetrating the fourth insulating layer 114. The fourth through electrode 134 can electrically connect between the fourth circuit layer 124 and the fifth circuit layer 125.

In addition, the through electrode includes a fifth through electrode 135 penetrating the fifth insulating layer 115. The fifth through electrode 135 can electrically connect between the fifth circuit layer 125 and the sixth circuit layer 126.

In addition, the circuit board includes a protective layer. The protective layer can be disposed on an uppermost or lowermost side of the circuit board. The protective layer can protect a surface of the circuit layer or the insulating layer disposed on the uppermost or lowermost side of the circuit board.

Preferably, the protective layer can include a first protective layer 140 disposed on an upper surface of the third insulating layer 113. The first protective layer 140 can protect an upper surface of the third insulating layer 113 and an upper surface of the third circuit layer 123. In addition, the first protective layer 140 may include a first opening (not shown) that overlaps at least a portion of an upper surface of the third circuit layer 123 in a thickness direction. The first opening may be formed to correspond to a mounting position of an electronic device or a contact position with an external substrate.

In addition, the protective layer may include a second protective layer 150 disposed on a lower surface of the fifth insulating layer 115. The second protective layer 150 may protect a lower surface of the fifth insulating layer 115 and a lower surface of the sixth circuit layer 126. In addition, the second protective layer 150 may include a second opening (not shown) that overlaps at least a portion of a lower surface of the sixth circuit layer 126 in a thickness direction. The second opening may be formed to correspond to a mounting position of an electronic device or a contact position with an external substrate.

At this time, the first protective layer 140 and the second protective layer 150 may be a solder resist, but are not limited thereto.

Meanwhile, the circuit board of the embodiment may include a plurality of regions. For example, the circuit board may include a first region R1, a second region R2, and a third region R3. For example, the insulating layer 110 may include a first region R1, a second region R2, and a third region R3. For example, the circuit layer 120 may include a first region R1, a second region R2, and a third region R3. For example, the first protective layer 140 may include a first region R1, a second region R2, and a third region R3.

At this time, the first protective layer 140 of the embodiment may have different structures for each region. For example, the first protective layer 140 of the embodiment may have different heights or opening structures in the first region R1, the second region R2, and the third region R3. Hereinafter, an outermost insulating layer, an outermost circuit layer, and an outermost protective layer will be described. Preferably, an insulating layer disposed at an uppermost side of the circuit board, a circuit layer disposed at the uppermost side, and a protective layer disposed at the uppermost side will be described below. The insulating layer, the circuit layer, and the protective layer described below may refer to the insulating layer, the circuit layer, and the protective layer disposed at the uppermost side of the circuit board, but are not limited thereto. For example, the insulating layer, the circuit layer, and the protective layer described below may refer to the insulating layer, the circuit layer, and the protective layer disposed at the lowermost side of the circuit board.

Accordingly, hereinafter, the third insulating layer 113 disposed at the uppermost side of the circuit board is referred to as an insulating layer 110, the third circuit layer 123 disposed at the uppermost side is referred to as a circuit layer 120, and the first protective layer 140 disposed at the uppermost side is referred to as a protective layer 140.

The first region R1, the second region R2, and the third region R3 may be distinguished based on a difference in a structure of an open region of the protective layer 140. The first region R1, the second region R2, and the third region R3 may be distinguished based on a type of configuration disposed on the circuit board. The first region R1, the second region R2, and the third region R3 may be distinguished based on a line width and a spacing of a pad and a trace of the circuit layer 120 disposed on the insulating layer 110.

The first region R1 may refer to a region where a chip such as a passive device is mounted on a circuit board. The second region R2 may refer to a region where an application chip is mounted on a circuit board. The third region R3 may refer to a region where a separate upper substrate (e.g., a memory substrate) is attached on the circuit board. Accordingly, structures of openings of the protective layer 140 in the first region R1, the second region R2, and the third region R3 may be different from each other.

Hereinafter, the first region R1, the second region R2, and the third region R3 of the embodiment will be described in detail.

For convenience of explanation, the structures of the second region R2 and the third region R3 will be described first, and the structure of the first region R1 will be described last.

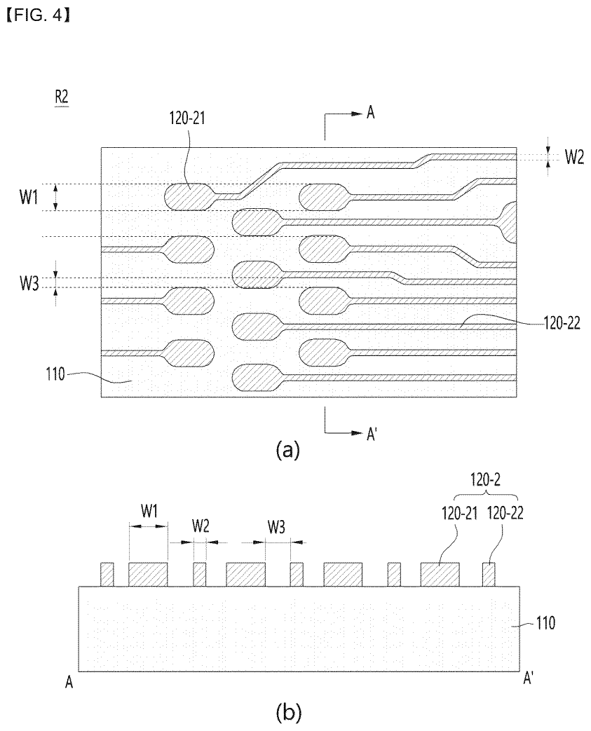

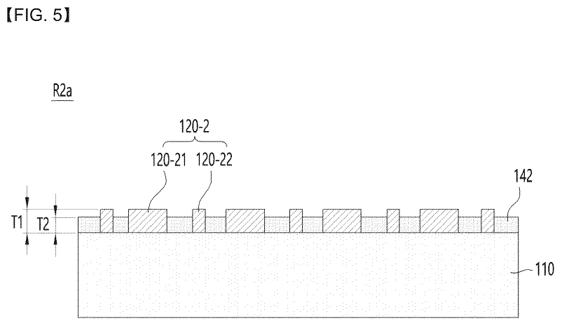

FIG. 4 is a view showing a structure of a second region of a circuit board according to a first embodiment, and FIG. 5 is a view showing a structure of a second region of a circuit board according to a second embodiment.

Referring to FIG. 4, a second pattern part 120-2 of the circuit layer 120 is disposed on the second region R2 of the insulating layer 110. FIG. 4 (a) is a plan view of a second region of the circuit board according to the first embodiment, and FIG. 4 (b) is a cross-sectional view taken along the A-A′ direction of FIG. 4 (a).

At this time, the second region R2 may mean a region where a fine circuit is required for mounting a processor chip or driver IC. Hereinafter, it will be described assuming that the chip mounted in the second region R2 is a processor chip.

The second pattern part 120-2 may mean a circuit pattern disposed in the second chip mounting region where the processor chip is mounted among the circuit layers 120. The second pattern part 120-2 includes a second pad 120-21 corresponding to a terminal of the processor chip and a second trace 120-22 connected to the second pad 120-21.

The second pattern part 120-2 requires miniaturization. For example, in the second region R2, pads connected to all terminals of the processor chip must be disposed within a limited space, while traces connected to pads connected to the terminals must be disposed. Accordingly, the second pattern part 120-2 may include a fine pattern.

In addition, recently, functions processed by a processor chip are increasing. Accordingly, it is difficult to implement all functions with one processor chip. Therefore, mounting of two or more processor chips with different functions on one circuit board is required.

Accordingly, if the processor chip includes first and second processor chips, miniaturization of the second pattern part 120-2 is required in order to connect all a wiring between the first processor chip and the second processor chips within a limited space.

In addition, a number of terminals in the first processor chip and the second processor chip is gradually increasing due to reasons such as 5G, Internet of Things (IoT), increased image quality, and increased communication speed. Accordingly, recently, a connection wiring between the first processor chip and the second processor chip may be two or more times, three or more times, or ten or more times than a conventional connection wiring.

Accordingly, in order to mount the first processor chip and the second processor chip on a single circuit board while minimizing a spacing between them and to connect the first processor chip and the second processor chip within a limited space, the second pattern part 120-2 is required to be ultra-fine.

A second pad 120-21 of the second pattern part 120-2 corresponds to a terminal of the processor chip to be mounted on the circuit board. Accordingly, a number of the second pads 120-21 corresponds to a number of terminals of the processor chip.

A width of the second pad 120-21 in a first horizontal direction and a width of the second pad 120-21 in a second horizontal direction perpendicular to the first horizontal direction may be different from each other. At this time, a width of the second pad 120-21 in a separation direction of neighboring pads or traces may be smaller than a width in a direction perpendicular to the separation direction. In addition, the width of the second pad 120-21 in the separation direction has a great influence on the circuit integration.

That is, the second pad 120-21 may have an elliptical shape whose width in the separation direction is smaller than the width in the direction perpendicular to the separation direction. However, the embodiment is not limited thereto. For example, the second pad 120-21 may have a circular shape having a width in the separation direction as a whole.

A width W1 of the second pad 120-21 may be 3 μm to 30 μm. For example, the width W1 of the second pad 120-21 may be 4 μm to 28 μm. For example, the width W1 of the second pad 120-21 may be 5 μm to 25 μm.

If the width W1 of the second pad 120-21 is smaller than 3 μm, it may be difficult to stably position the adhesive member that connects to the terminals of the processor chip. If the width W1 of the second pad 120-21 is smaller than 3 μm, the connection reliability between the second pad 120-21 and the processor chip may deteriorate. If the width W1 of the second pad 120-21 is greater than 30 μm, it may be difficult to place all the patterns connected to the processor chip within a limited space. If the width W1 of the second pad 120-21 is greater than 30 μm, a size of the circuit board may increase. If the width W1 of the second pad 120-21 is greater than 30 μm, a spacing between neighboring patterns is narrowed, and thus a reliability problem such as a circuit short may occur.

The second pattern part 120-2 disposed in the second region R2 includes a second trace 120-22 connected to the second pad 120-21. The second trace 120-22 may mean a thin and long signal line connected to the second pad 120-21. In addition, when two processor chips are mounted on the second pattern part 120-2, the second trace 120-22 may include a signal line connecting the two chips.

The second trace 120-22 may include an ultra-fine pattern. For example, a line width W2 of the second trace 120-22 may satisfy a range of 1 μm to 10 μm. For example, the line width W2 of the second trace 120-22 may satisfy a range of 1.2 μm to 8 μm. For example, the line width W2 of the second trace 120-22 may satisfy a range of 1.5 μm to 7 μm. If the line width W2 of the second trace 120-22 is smaller than 1 μm, a resistance of the second trace 120-22 increases, and thus normal communication with processor chips may become difficult. In addition, if the line width W2 of the second trace 120-22 is smaller than 1 μm, it may be difficult to apply a general circuit pattern manufacturing process. If the line width W2 of the second trace 120-22 is smaller than 1 μm, a physical reliability problem in which the second trace 120-22 collapses due to various factors may occur. If the line width W2 of the second trace 120-22 is greater than 10 μm, it may be difficult to arrange all signal lines connected to the terminals of the processor within a limited space. For example, if the line width W2 of the second trace 120-22 is greater than 10 μm, it may be difficult to arrange all traces for connecting the plurality of processor chips within a limited space. For example, if the line width W2 of the second trace 120-22 is greater than 10 μm, an area of the second region R2 may increase, and thus sizes of the circuit board and semiconductor package may increase.

Meanwhile, the second pattern parts 120-2 may be spaced apart from each other by a certain spacing W3 on the second region R2. The spacing W3 may mean a spacing between the second pads 120-21 of the second pattern part 120-2. In addition, the spacing W3 may mean a spacing between the second traces of the second pattern part 120-2. In addition, the spacing W3 may mean a spacing between the second pad 120-21 and the second trace 120-22 adjacent to each other of the second pattern part 120-2.

The spacing W3 may have a range of 1 μm to 10 μm. The spacing W3 may have a range of 1.2 μm to 8 μm. The spacing W3 may have a range of 1.5 μm to 7 μm. If the spacing W3 is smaller than 1 μm, there is a problem that the adjacent second traces or second pads are connected to each other, resulting in an electrical short circuit. For example, if the spacing W3 is greater than 10 μm, it may be difficult to place all traces for connecting a plurality of processor chips within a limited space.

As described above, relatively dense circuit patterns are disposed in the second region R2. For example, a second pattern part 120-2 having a smaller width and spacing than the first region R1 or the third region R3 is disposed in the second region R2. In addition, it may be difficult to form an SRO on the second pad 120-21 of the second pattern part 120-2 with an exposure resolution of a general solder resist. Accordingly, as in (b) of FIG. 4, the protective layer 140 may not be disposed in the second region R2. In other words, the protective layer 140 may not vertically overlap with the second region R2. That is, the second pattern part 120-2 disposed in the second region R2 is a fine pattern, and a SRO of the protective layer 140 may be difficult to form corresponding to the fine pattern in the second region R2 due to a limitation in resolution for forming the SRO of the protective layer 140.

Meanwhile, referring to FIG. 5, the second trace 120-22 disposed in the second region R2 is a fine pattern and is a pattern disposed on an outermost layer. In addition, the second trace 120-22 has a structure that protrudes on the upper surface of the insulating layer 110. Accordingly, damage may be applied to the second trace 120-22 during a subsequent manufacturing process while the second trace 120-22 is formed. As a result, a problem may occur in the physical reliability of the second trace 120-22.

Accordingly, a third protective pattern 142 of a protective layer 140 may be formed in a second region R2a of a second embodiment.

At this time, the third protective pattern 142 may have the same height or thickness on the second region R2a as a whole. Here, the third protective pattern 142 having the same height or thickness as a whole may mean that a height difference of an upper surface of the third protective pattern 142 in the second region R2a is 3 μm or less, 2 μm or less, 1 μm or less, and 0.5 μm or less.

At this time, a thickness T1 of the second pattern part 120-2 disposed in the second region R2a may be 10 μm to 25 μm.

In addition, the third protective pattern 142 of the protective layer 140 may have a thickness T2 smaller than the thickness T1 of the second pattern part 120-2. For example, the thickness T2 of the third protective pattern 142 may satisfy a range of 40% to 90% of the thickness T1 of the second pattern part 120-2. Preferably, the thickness T2 of the third protective pattern 142 may satisfy a range of 45% to 85% of the thickness T1 of the second pattern part 120-2. For example, the thickness T2 of the third protective pattern 142 may satisfy a range of 50% to 80% of the thickness T1 of the second pattern part 120-2.

For example, the thickness T2 of the third protective pattern 142 may be 4 μm to 22 μm. For example, the thickness T2 of the third protective pattern 142 may be 4.5 μm to 21 μm. For example, the thickness T2 of the third protective pattern 142 may be 5 μm to 20 μm.

If the thickness T2 of the third protective pattern 142 is less than 40% of the thickness T1 of the second pattern part 120-2, an effect of protecting the second pattern part 120-2 by the third protective pattern 142 may be insufficient. In addition, if the thickness T2 of the third protective pattern 142 is greater than 90% of the thickness T1 of the second pattern part 120-2, a residual resin of the protective layer 140 may remain on the upper surface of the second pattern portion 120-2. In addition, if the residual resin remains, a problem may occur in electrical reliability.

As in the first embodiment, an upper surface and a side surface of the second pattern part 120-2 in the second region R2 may not entirely contact the protective layer 140.

In addition, the upper surface of the second pattern part 120-2 in the second region R2a in the second embodiment may not entirely contact the protective layer 140. In addition, a side surface of the second pattern part 120-2 in the second region R2a in the second embodiment may be partially covered by the protective layer 140. For example, at least a portion of the side surface of the second pattern part 120-2 may be covered with the protective layer 140, while another portion of the side surface of the second pattern part 120-2 may not be in contact with the protective layer 140.

That is, in the second embodiment, a process for thinning the thickness of the protective layer (for example, a thinning process, or a forming process of the protective layer of the first region described below) can be performed in a state in which the protective layer covering the entire upper surface of the second pattern part 120-2 is formed on the second region R2a. Accordingly, the protective layer 140 of the second embodiment may include a third protective pattern disposed in the second region R2a and having a height lower than that of the upper surface of the second pattern part 120-2 as a whole.

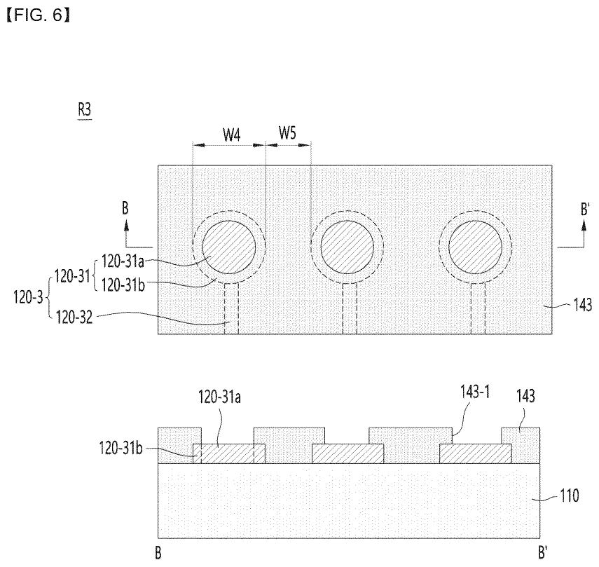

FIG. 6 is a view showing a structure of a third region of a circuit board according to an embodiment.

FIG. 6 (a) is a plan view of a third region of the circuit board of the embodiment, and FIG. 6 (b) is a cross-sectional view cut along the B-B′ direction of FIG. 6 (a).

Referring to (a) and (b) of FIG. 6, a third pattern part 120-3 having a relatively greater width and spacing than a second pattern part 120-2 disposed in a second region R2 is disposed in a third region R3.

The third region R3 refers to a region where pads or bumps connected to a separate package substrate such as a memory substrate are disposed.

The third pattern part 120-3 includes a third pad 120-31 and a third trace 120-3.

A width W4 of the third pad 120-31 satisfies a range of 30 μm to 70 μm. For example, the width W4 of the third pad 120-31 satisfies a range of 35 μm to 65 μm. For example, the width W4 of the third region R3 satisfies a range of 35 μm to 50 μm.

In addition, a spacing W5 between neighboring patterns in the third region R3 satisfies a range of 10 μm to 40 μm. For example, the spacing W5 between neighboring patterns in the third region R3 satisfies a range of 12 μm to 30 μm. For example, the spacing W5 between neighboring patterns in the third region R3 satisfies a range of 13 μm to 25 μm.

In addition, unlike the second region R2, the third trace 120-3 of the third pad 120-31 disposed in the third region R3 does not require a fine line width or fine spacing.

Therefore, a protective layer 140 having a structure different from that of the second region R2 is formed in the third region R3.

For example, the protective layer 140 includes a fourth protective pattern 143 disposed in the third region R3.

The fourth protective pattern 143 is disposed in the third region R3 with a thickness greater than that of the third pad 120-31. At this time, the fourth protective pattern 143 may be disposed to cover at least a portion of the upper surface of the third pad 120-31. In addition, the fourth protective pattern 143 includes an opening 143-1 that overlaps at least a portion of the upper surface of the third pad 120-31 in the thickness direction.

That is, a side surface of the third pad 120-31 may be entirely covered with the fourth protective pattern 143 of the protective layer 140.

In addition, an upper surface of the third pad 120-31 may be partially covered with the fourth protective pattern 143 of the protective layer 140.

Specifically, the third pad 120-31 may include a first portion 120-31a that overlaps the opening 143-1 of the fourth protective pattern 143 of the protective layer 140 in the thickness direction, and a second portion 120-31b that is covered with the fourth protective pattern 143.

In addition, the upper surface of the third trace 120-3 may be entirely covered with the fourth protective pattern 143 of the protective layer 140. However, the embodiment is not limited thereto, and a part of the upper surface of the third trace 120-3 adjacent to the third pad 120-31 may not be in contact with the fourth protective pattern 143 of the protective layer 140.

In conclusion, the protective layer 140 in the third region R3 may have an SMD structure.

As described above, the protective layer 140 of the embodiment has different structures in the second region R2 and the third region R3.

For example, the protective layer 140 may not be disposed in the second region R2. In contrast, the protective layer 140 may not entirely contact the upper surface of the second pattern part 120-2 in the second region R2a. For example, the protective layer 140 may be positioned lower than the upper surface of the second pattern part 120-2 in the second region R2a.

In addition, the protective layer 140 may be positioned higher than the upper surface of the third pattern part 120-3 in the third region R3. For example, the protective layer 140 may cover at least a portion of the upper surface of the third pattern part 120-3 in the third region R3. For example, the protective layer 140 may have an SMD structure in the third region R3.

Meanwhile, the protective layer 140 in the first region R1 may have a different structure from the second region R2 and/or the third region R3. Here, the different structure may mean that a structure of an open portion formed in the protective layer 140 is different, and may mean that the height or thickness is different.

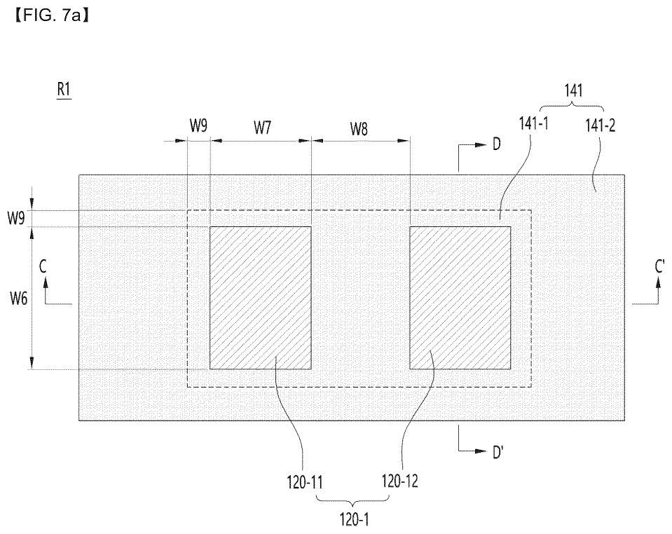

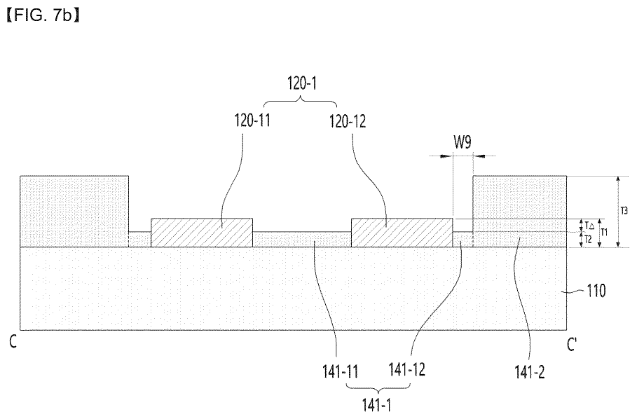

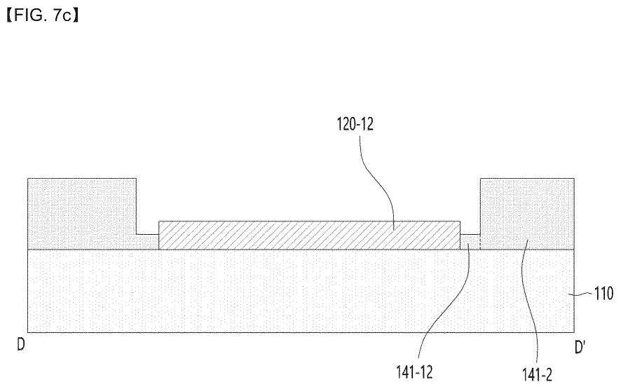

FIG. 7a is a plan view of a first region of a circuit board according to a first embodiment, FIG. 7b is a cross-sectional view taken along a C-C′ direction of FIG. 7a, FIG. 7c is a cross-sectional view taken along a D-D′ direction of FIG. 7a, and FIG. 8 is a perspective view showing a semiconductor device mounted on a first region of a circuit board according to one embodiment.

Hereinafter, a first region of the circuit board according to the embodiment will be described in detail with reference to FIGS. 7a to 8.

In the first region R1, a first pattern part 120-1 having a relatively larger width and spacing than the pattern parts disposed in the second region R2 and the third region R3 is disposed. At this time, the first pattern part 120-1 includes a plurality of pads. At this time, traces may not be disposed in the first region R1. That is, the first pattern part 120-1 may include only a plurality of pads. For example, the first pattern part 120-1 may include only island pads that are not directly connected to other patterns disposed on the upper surface of the insulating layer 110, and may be disposed in the first region R1. However, the embodiment is not limited thereto, and in some cases, a trace connected to the first pattern part 120-1 may be disposed in the first region R1.

The first pattern part 120-1 includes a first pad. For example, the first pattern part 120-1 includes a first-first pad 120-11 and a first-second pad 120-12 connected to one first semiconductor device.

The first-first pad 120-11 may be a pad connected to a first terminal of the first semiconductor device, and the first-second pad 120-12 may be a pad connected to a second terminal of the first semiconductor device. In addition, although the first pad connected to one first semiconductor device is illustrated in the drawing, the embodiment is not limited thereto. For example, a plurality of first pads connected to at least two or more first semiconductor devices may be disposed in the first region R1. In addition, each of the plurality of first pads may include a first-first pad and a first-second pad.

The first-first pad 120-11 and the first-second pad 120-12 may be large-area pads. For example, a terminal of a first chip has a relatively large size. Here, having a relatively large size may mean that a size of each terminal provided in the first chip is larger than a size of each terminal of a second chip, such as the processor chip.

The first-first pad 120-11 and the first-second pad 120-12 may be spaced apart from each other in a first horizontal direction. The first horizontal direction may mean a width direction, a x-axis direction, and a horizontal direction in the drawing.

The first-first pad 120-11 and the first-second pad 120-12 may have a width W6 in a second horizontal direction perpendicular to the first horizontal direction greater than a width W7 in the first horizontal direction.

The width W6 in the second horizontal direction of each of the first-first pad 120-11 and the first-second pad 120-12 may satisfy a range of 125% to 220% of the width W7 in the first horizontal direction. The width W6 of each of the first-first pad 120-11 and the first-second pad 120-12 in the second horizontal direction can satisfy a range of 130% to 210% of the width W7 in the first horizontal direction. The width W6 of each of the first-first pad 120-11 and the first-second pad 120-12 in the second horizontal direction can satisfy a range of 140% to 200% of the width W7 in the first horizontal direction.

If the width W6 of each of the first-first pad 120-11 and the first-second pad 120-12 in the second horizontal direction is smaller than 125% of the width W7 in the first horizontal direction, it may be difficult to stably place the first semiconductor device. If the width W6 of each of the first-first pad 120-11 and the first-second pad 120-12 in the second horizontal direction is smaller than 125% of the width W7 in the first horizontal direction, mounting characteristics of the first chip or electrical reliability with the first semiconductor device may be deteriorated. If the width W6 of each of the first-first pad 120-11 and the first-second pad 120-12 in the second horizontal direction exceeds 220% of the width W7 in the first horizontal direction, an arrangement space of the first pattern part 120-1 may increase, and thus a size of the circuit board may increase.

For example, the width W6 of each of the first-first pad 120-11 and the first-second pad 120-12 in the second horizontal direction may have a range of 210 μm±15 μm. In addition, when the width W6 in the second horizontal direction has a range of 210 μm±15 μm, the width W7 in the first horizontal direction can have a range of 140 μm±15 μm.

For example, the width W6 in the second horizontal direction of each of the first-first pad 120-11 and the first-second pad 120-12 can have a range of 310 μm±15 μm. In addition, when the width W6 in the second horizontal direction has a range of 310 μm±15 μm, the width W7 in the first horizontal direction can have a range of 190 μm±15 μm.

For example, the width W6 in the second horizontal direction of each of the first-first pad 120-11 and the first-second pad 120-12 can have a range of 660 μm±15 μm. In addition, when the width W6 in the second horizontal direction has a range of 660 μm±15 μm, the width W7 in the first horizontal direction can have a range of 450 μm±15 μm.

Preferably, the width W6 in the second horizontal direction of each of the first-first pad 120-11 and the first-second pad 120-12 can exceed 195 μm. Preferably, the width W6 in the second horizontal direction of each of the first-first pad 120-11 and the first-second pad 120-12 can exceed 295 μm. Preferably, the width W6 in the second horizontal direction of each of the first-first pad 120-11 and the first-second pad 120-12 can exceed 645 μm.

Preferably, the width W7 of each of the first-first pad 120-11 and the first-second pad 120-12 in the first horizontal direction may exceed 125 μm. Preferably, the width W7 of each of the first-first pad 120-11 and the first-second pad 120-12 in the first horizontal direction may exceed 175 μm. Preferably, the width W7 of each of the first-first pad 120-11 and the first-second pad 120-12 in the first horizontal direction may exceed 435 μm.

Meanwhile, a spacing W8 between the first-first pad 120-11 and the first-second pad 120-12 in the first region R1 can satisfy a range of 70% to 120% of the width W7 of each of the first-first pad 120-11 and the first-second pad 120-12 in the first horizontal direction. The spacing W8 between the first-first pad 120-11 and the first-second pad 120-12 in the first region R1 can satisfy a range of 75% to 115% of the width W7 of each of the first-first pad 120-11 and the first-second pad 120-12 in the first horizontal direction. The spacing W8 between the first-first pad 120-11 and the first-second pad 120-12 in the first region R1 can satisfy a range of 80% to 110% of the width W7 of each of the first-first pad 120-11 and the first-second pad 120-12 in the first horizontal direction.

If the spacing W8 between the first-first pad 120-11 and the first-second pad 120-12 in the first region R1 is smaller than 70% of the width W7 of each of the first-first pad 120-11 and the first-second pad 120-12 in the first horizontal direction, a circuit short circuit problem may occur as a plurality of adhesive members are connected to each other in a process of mounting the first chip. If the spacing W8 between the first-first pad 120-11 and the first-second pad 120-12 in the first region R1 exceeds 120% of the width W7 of each of the first-first pad 120-11 and the first-second pad 120-12 in the first horizontal direction, connectivity with the first semiconductor device may be deteriorated.

As described above, a first pattern part 120-1 having a relatively large width and a relatively large spacing is disposed in the first region R1 of the circuit board. Accordingly, an open structure of the protective layer 140 in the first region R1 generally has an SMD structure. That is, as in the first comparative example, the protective layer 140 in the first region of the general circuit board has an SMD structure that covers at least a part of the upper surface of the first pattern part.

In contrast, the embodiment allows the protective layer 140 to have a new open structure so as not to affect an increase in the thickness of the semiconductor package by the protective layer 140 while disposed in the first region R1.

That is, the protective layer 140 includes a protective portion 141 disposed in the first region R1.

The protective portion 141 may have different heights depending on a location. Preferably, the protective portion 141 contacts at least a part of the side surface of the first pattern part 120-1 without contacting the upper surface of the first pattern part 120-1. Here, a fact that the protective portion 141 contacts at least a part of the side surface of the first pattern part 120-1 means that at least a part of the side surface of the first pattern part 120-1 does not contact the first protective layer 140.

The protective portion 141 includes a first protective pattern 141-1 adjacent to the first pattern part 120-1 in the first region R1 and a second protective pattern 141-2 other than the first protective pattern 141-1.

At this time, the embodiment may perform a process of thinning a thickness of the protective layer 140 so that the first protective pattern 141-1 and the second protective pattern 141-2 are provided in the protective layer 140. At this time, an inner wall of the second protective pattern 141-2 may have a slope along the thickness direction of the protective layer 140. For example, the inner wall of the second protective pattern 141-2 may have a slope whose width changes along the thickness direction. Preferably, the inner walls of the first protective pattern 141-1 and the second protective pattern 141-2 of the embodiment are provided by a process of selectively thinning the thickness of the protective layer 140, and thus may have a curved surface of a certain curvature whose width decreases along the thickness direction.

Accordingly, the embodiment may have the inner wall of the second protective pattern 141-2 have a curved surface, and thus may improve a contact area between the second protective pattern 141-2 and a molding layer. Therefore, the embodiment may solve a problem of the molding layer being peeled off from the protective layer, and further may enable the semiconductor device to be more stably fixed by the molding layer.

In addition, since the inner wall of the second protective pattern 141-2 has a curved surface, the embodiment can increase a distance between the upper surface of the protective layer 140 corresponding to the curvature of the curved surface and the first pattern part 120-1. At this time, the semiconductor package may experience stress due to a heat cycle such as expansion and/or contraction in a manufacturing process and/or usage environment. At this time, the stress may be transmitted to the first pattern part 120-1, and thus may affect the electrical reliability of the first semiconductor device mounted on the first pattern part 120-1. For example, when the stress is transmitted to an interface between the first pattern part 120-1 and the first semiconductor device, a crack may occur, and a reliability problem may occur in which the first semiconductor device is electrically separated from the first pattern part 120-1. On the other hand, the embodiment may allow the inner wall of the second protective pattern 141-2 to have a curved surface, thereby preventing stress from being transferred to an interface between the first semiconductor device and the first pattern part 120-1, thereby improving the electrical reliability and/or physical reliability of the semiconductor package.

The first protective pattern 141-1 may be disposed in a region adjacent to the first pattern part 120-1 in the first region R1. The second protective pattern 141-2 can be disposed in an edge region of the first region R1 excluding a region where the first protective pattern 141-1 is disposed.

For example, the first protective pattern 141-1 may be disposed to surround at least a portion of the side surface of the first-first pad and the first-second pad of the first pattern part 120-1, and may be disposed between the first-first pad and the first-second pad. In addition, the second protective pattern 141-2 may be provided to surround the first protective pattern 141-1.

For example, the first protective pattern 141-1 may be disposed in a peripheral region of surfaces of the first-first pad 120-11 and the first-second pad 120-12. In addition, the first protective pattern 141-1 may be disposed in a region between the first-first pad 120-11 and the first-second pad 120-12. For example, the first protective pattern 141-1 includes a first portion 141-11 disposed between the first-first pad 120-11 and the first-second pad 120-12. In addition, the first protective pattern 141-1 includes a second portion 141-12 surround a side surface of the first-first pad 120-11, a side surface of the first-second pad 120-12, and a side surface of the first portion 141-11.

That is, the first protective pattern 141-1 may be disposed to surround a peripheral region of the first pattern part 120-1, including a region between the first-first pad 120-11 and the first-second pad 120-12, in the first region R1.

An upper surface of the first protective pattern 141-1 may be positioned lower than an upper surface of the first pattern part 120-1. That is, a thickness T2 of the first protective pattern 141-1 may be smaller than a thickness T1 of the first pattern part 120-1.

The thickness T1 of the first pattern part 120-1 may be 10 μm to 25 μm. Preferably, the thickness T1 of the first pattern part 120-1 may be 12 μm to 23 μm. More preferably, the thickness T1 of the first pattern part 120-1 may have a thickness of 12 μm to 20 μm.

The thickness T2 of the first protective pattern 141-1 may be 3 μm to 21μm. The thickness T2 of the first protective pattern 141-1 may be 4 μm to 19 μm. The thickness T2 of the first protective pattern 141-1 may be 5 μm to 16 μm.

If the thickness T2 of the first protective pattern 141-1 is 3 μm or less, an effect produced by the first protective pattern 141-1 according to an embodiment may be insignificant. For example, if the thickness T2 of the first protective pattern 141-1 is 3 μm or less, a short-circuit prevention effect between the plurality of adhesive members to be disposed on the first-first pad 120-11 and the first-second pad 120-12 may be insufficient. For example, if the thickness T2 of the first protective pattern 141-1 is 3 μm or less, there may be a limit to reducing the spacing between the first-first pad 120-11 and the first-second pad 120-12. For example, if the thickness T2 of the first protective pattern 141-1 exceeds 21 μm, a problem may occur in which residual resin of the protective layer 140 remains on the first-first pad 120-11 or the first-second pad 120-12. For example, if the thickness T2 of the first protective pattern 141-1 exceeds 21 μm, a reliability problem may occur in which at least a portion of the upper surface of the first-first pad 120-11 or the first-second pad 120-12 is covered by the first protective pattern 141 due to a process error.

In addition, the thickness T2 of the first protective pattern 141-1 may satisfy a range of 40% to 90% of the thickness T1 of the first pattern part 120-1. Preferably, the thickness T2 of the first protective pattern 141-1 may satisfy a range of 45% to 85% of the thickness T1 of the first pattern part 120-1. For example, the thickness T2 of the first protective pattern 141-1 can satisfy a range of 50% to 80% of the thickness T1 of the first pattern part 120-1.

Meanwhile, in the embodiment, a height difference (TΔ) between an upper surface of the first pattern part 120-1 and an upper surface of the first protective pattern 141-1 is set to be 3 μm or more. The height difference (TΔ) may mean a vertical distance between the upper surface of the first pattern part 120-1 and the upper surface of the first protective pattern 141-1.

In the embodiment, the height difference (TΔ) between the upper surface of the first pattern part 120-1 and the upper surface of the first protective pattern 141-1 is set to be 3.5 μm or more. More preferably, in the embodiment, the height difference (TΔ) between the upper surface of the first pattern part 120-1 and the upper surface of the first protective pattern 141-1 is set to be 4 μm or more. At this time, the upper surface of the first pattern part 120-1 may not be a plane, and the upper surface of the protective portion 141 may not be a plane. At this time, the height difference (TA) may mean a height difference between an uppermost end of the first pattern portion 120-1 and an uppermost end of the first protective pattern 141-1.

If the height difference (TΔ) between the upper surface of the first pattern part 120-1 and the upper surface of the first protective pattern 141-1 is less than 3 μm, a problem may occur in which residual resin remains on the upper surface of the first pattern part 120-1 or in which at least a part of the upper surface of the first pattern part 120-1 is covered with the first protective pattern 141-1 due to a process error.

Preferably, the height difference (TΔ) between the upper surface of the first pattern part 120-1 and the upper surface of the first protective pattern 141-1 is 3 μm to 10 μm. As a result, a first protective pattern 141-1 having an optimal height can be provided regardless of the thickness of the first pattern part 120-1. That is, if the height difference (TΔ) exceeds 10 μm, the effect produced by the first protective pattern 141-1 may be insignificant.

Meanwhile, the protective portion 141 includes a second protective pattern 141-2 disposed around the first protective pattern 141-1. The second protective pattern 141-2 may have a thickness greater than that of the first protective pattern 141-1. In addition, the second protective pattern 141-2 may have a thickness greater than that of the first pattern part 120-1.

Preferably, the upper surface of the second protective pattern 141-2 may be positioned higher than the upper surface of the first protective pattern 141-1. Furthermore, the upper surface of the second protective pattern 141-2 may be positioned higher than the upper surface of the first pattern part 120-1.

The thickness T3 of the second protective pattern 141-2 may be 17 μm to 45 μm. Preferably, the thickness T3 of the second protective pattern 141-2 may be 19 μm to 43 μm. More preferably, the thickness T3 of the second protective pattern 141-2 may have a thickness of 19 μm to 40 μm.

The second protective pattern 141-2 is disposed to surround the first protective pattern 141-1.

At this time, the width W9 between the first pattern part 120-1 of the first protective pattern 141-1 and the second protective pattern 141-2 may have a range of 13 μm to 25 μm. Preferably, the width W9 between the first pattern part 120-1 of the first protective pattern 141-1 and the second protective pattern 141-2 may have a range of 15 μm to 23 μm. The width W9 between the first pattern part 120-1 and the second protective pattern 141-2 of the first protective pattern 141-1 may have a range of 16 μm to 20 μm.

Specifically, the first-first pad 120-11 includes a plurality of side surfaces. The plurality of side surfaces of the first-first pad 120-11 include a first-first side surface facing the side surface of the first-second pad 120-12 and a first-second side surface other than the first-first side surface. In addition, the width W9 may mean a horizontal distance between the first-second side surface of the first-first pad 120-11 and the inner wall of the second protective pattern 141-2 adjacent to the first-second side surface.

In addition, the first-second pad 120-12 includes a plurality of side surfaces. The plurality of side surfaces of the first-second pad 120-12 include the second-first side surface facing the first-first side surface of the first-first pad 120-11, and the second-second side surface excluding the second-first side surface. In addition, the width W9 may mean a horizontal distance between the second-second side surface of the first-second pad 120-12 and the inner wall of the second protective pattern 141-2 of the first protective layer 140 adjacent to the second-second side surface.

If the width W9 is smaller than 13 μm, a problem may occur in which the second protective pattern 141-2 of the protective layer 140 overlaps the first chip in the thickness direction due to a manufacturing process error. For example, a design of the first-first pad 120-11 and the first-second pad 120-12 is performed by considering the process error in the arrangement process of the first semiconductor device. For example, the first semiconductor device may be disposed on the first-first pad 120-11 and the first-second pad 120-12 with a certain error range. In addition, the width W9 may be a value considering the error range. At this time, if the width W9 is smaller than 13 μm, a problem may occur in which the error range is not sufficiently covered, and accordingly, a problem may occur in which at least a part of the first chip comes into contact with the second protective pattern 141-2 during a mounting process of the first chip. In addition, if the width W9 exceeds 25 μm, an area of the first region R1 increases, and accordingly, an overall size of the circuit board may increase.

Meanwhile, referring to FIG. 8, a design of the first region R1 as described above is set based on a size of the first semiconductor device 200 disposed on the first-first pad 120-11 and the first-second pad 120-12. At this time, the first semiconductor device 200 may be various devices, but may be, for example, a multi-layered ceramic capacitor.

The first semiconductor device 200 includes a body 210. In addition, the first semiconductor device 200 includes a first terminal 220 disposed on one side of the body 210 and connected to the first-first pad 120-11. In addition, the first semiconductor device 200 includes a second terminal 230 disposed on other side of the body 210 and connected to the first-second pad 120-12. The first terminal 220 and the second terminal 230 may be disposed to be spaced apart in a second horizontal direction, which is a separation direction of the first-first pad 120-11 and the first-second pad 120-12.

The first semiconductor device 200 may have a width (L) in the second horizontal direction greater than a width (W) in the first horizontal direction perpendicular to the second horizontal direction.

The width (L) of the first semiconductor device 200 in the second horizontal direction may satisfy a range of 125% to 220% of the width (W) in the first horizontal direction. The width (L) of the first semiconductor device 200 in the second horizontal direction may satisfy a range of 130% to 210% of the width (W) in the first horizontal direction. The width (L) of the first semiconductor device 200 in the second horizontal direction may satisfy a range of 140% to 200% of the width (W) in the first horizontal direction.

For example, the width (W) of the first semiconductor device 200 in the first horizontal direction may have a range of 200 μm±15 μm, and the width (L) of the second horizontal direction may have a range of 400 μm±15 μm. In addition, in this case, the thickness (T) of the first semiconductor device 200 may have a range of 200 μm±50 μm.

As another example, the width (W) of the first semiconductor device 200 in the first horizontal direction may have a range of 300 μm±15 μm, and the width (L) of the second horizontal direction may have a range of 600 μm±15 μm. In this case, the thickness (T) of the first semiconductor device 200 may have a range of 400 μm±100 μm.

As another example, the width (W) of the first semiconductor device 200 in the first horizontal direction may have a range of 500 μm±15 μm, and the width (L) of the second horizontal direction may have a range of 1000 μm±15 μm. In addition, in this case, the thickness (T) of the first semiconductor device 200 may have a range of 450 μm±250 μm.

As another example, the width (W) of the first semiconductor device 200 in the first horizontal direction may have a range of 800 μm±15 μm, and the width (L) of the second horizontal direction may have a range of 1500 μm±15 μm.

As another example, the width (W) of the first semiconductor device 200 in the first horizontal direction may have a range of 1300 μm±15 μm, and the width (L) in the second horizontal direction may have a range of 2000 μm±15 μm.

As another example, the width (W) of the first semiconductor device 200 in the first horizontal direction may have a range of 2000 μm±15 μm, and the width (L) in the second horizontal direction may have a range of 2500 μm±15 μm.

As another example, the width (W) of the first semiconductor device 200 in the first horizontal direction may have a range of 1500 μm±15 μm, and the width (L) in the second horizontal direction may have a range of 3000 μm±15 μm.

As another example, the width (W) of the first semiconductor device 200 in the first horizontal direction may have a range of 2500 μm±15 μm, and the width (L) in the second horizontal direction may have a range of 3200 μm±15 μm.

As another example, the width (W) of the first semiconductor device 200 in the first horizontal direction may have a range of 1600 μm±15 μm, and the width (L) in the second horizontal direction may have a range of 4500 μm±15 μm.

As another example, the width (W) of the first semiconductor device 200 in the first horizontal direction may have a range of 3000 μm±15 μm, and the width in the second horizontal direction may have a range of 4600 μm±15 μm.

As another example, the width (W) of the first semiconductor device 200 in the first horizontal direction may have a range of 250 μm±15 μm, and the width (L) in the second horizontal direction may have a range of 5000 μm±15 μm.

As another example, the width (W) of the first semiconductor device 200 in the first horizontal direction may have a range of 3200 μm±15 μm, and the width (L) in the second horizontal direction may have a range of 6300 μm±15 μm.

As another example, the width (W) of the first semiconductor device 200 in the first horizontal direction may have a range of 6300 μm±15 μm, and the width in the second horizontal direction may have a range of 6900 μm±15 μm.

As another example, the width (W) of the first semiconductor device 200 in the first horizontal direction may have a range of 5100 μm±15 μm, and the width (L) in the second horizontal direction may have a range of 7400 μm±15 μm.

The circuit board of the embodiment includes a first region in which a first semiconductor device is arranged.

In addition, the circuit board includes a first-first pad and a first-second pad. The first-first pad and the first-second pad are provided so as to overlap the first semiconductor device in a vertical direction. For example, the first-first pad and the first-second pad are provided in a first region of the circuit board. In addition, the embodiment includes a protective layer. The protective layer includes a first protective pattern disposed between the first-first pad and the first-second pad, and surrounding at least a portion of a side surface of the first-first pad and a side surface of the first-second pad. In addition, the protective layer includes a second protective pattern provided surrounding the first protective pattern.

The first protective pattern contacts at least a portion of a side surface of the first-first pad and the first-second pad without contacting upper surfaces of the first-first pad and the first-second pad. For example, an upper surface of the first protective pattern is positioned lower than the upper surfaces of the first-first pad and the first-second pad. Therefore, the embodiment can reduce a thickness and a width of a contact member to be disposed on the first-first pad and the first-second pad by using the first protective pattern.

For example, a first comparative example has a problem in that a thickness of the contact member increases due to an arrangement of the protective layer, and the second comparative example had a problem in that an degree of expansion of the contact member increased due to an non-arrangement of the protective layer, thereby increasing the width of the contact member.

In contrast, the embodiment can reduce the degree of expansion of the contact member and reduce the width of the contact member by using a combination of the first and second protective patterns. In addition, the embodiment provides only the first protective pattern in a region that vertically overlaps the first semiconductor device. For example, the second protective pattern does not vertically overlap the first semiconductor device. Therefore, the embodiment can prevent a thickness of the contact member from increasing due to a height of the protective layer.

Accordingly, the embodiment can reduce a thickness of the semiconductor package, thereby achieving miniaturization. Furthermore, the embodiment can solve a problem of a circuit short between adjacent contact members by reducing the degree of expansion of the contact member. As a result, the embodiment can improve the electrical reliability and product reliability of the semiconductor package. Furthermore, the embodiment can solve the problem of a circuit short without increasing a spacing between the first-first pad and the first-second pad, thereby improving circuit integration.

In addition, the embodiment can solve a problem of an adhesive member penetrating between an insulating layer and a pad by using the first protective pattern, thereby further improving product reliability.

Meanwhile, it was explained that the vertical cross-section of the first pattern part 120-1 in the first embodiment has a square shape, and accordingly, the upper surface of the first pattern part 120-1 is a plane, and at least a part of the side surface of the first pattern part 120-1 does not contact the first protective pattern 141 of the protective layer 140.

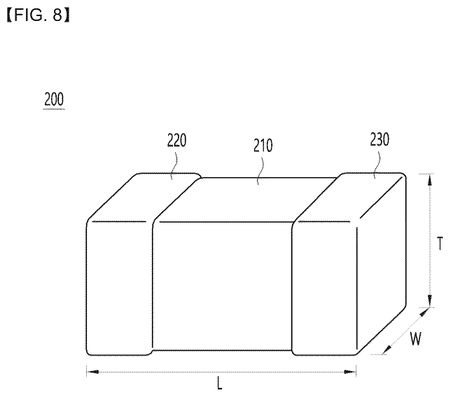

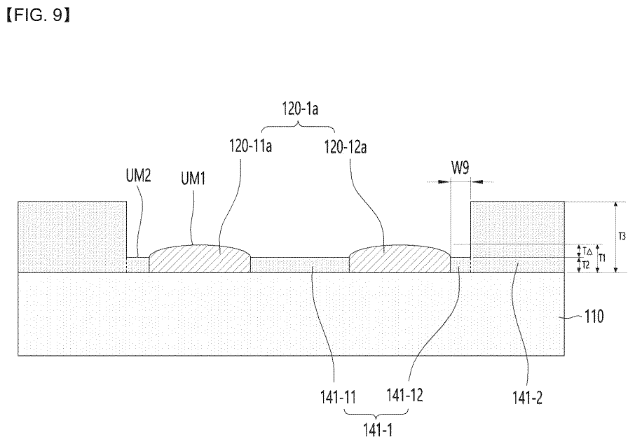

FIG. 9 is a plan view of a first region of a circuit board according to a second embodiment.

Referring to FIG. 9, the first pattern part 120-1a may be deformed during a process of forming the circuit pattern. For example, an upper surface of the first pattern part 120-1a may have a curved surface rather than a flat surface.

Accordingly, upper surfaces of the first pad 120-11a and the second pad 120-12a of the first pattern part 120-1a may change in height along the horizontal direction.

As shown in FIG. 9, when the upper surfaces of the first pad 120-11a and the second pad 120-12a have a curved surface, it may be difficult to determine exactly where the upper surfaces of the first pad 120-11a and the second pad 120-12a extend.

In this case, upper surfaces of the first pad 120-11a and the second pad 120-12a in the second embodiment may mean a start portion to an end portion of the curved surface.

Accordingly, the first protective pattern 141-1 of the protective layer 140 may completely cover the side surfaces of the first pad 120-11a and the second pad 120-12a, or may partially cover the side surfaces of the first pad 120-11a and the second pad 120-12a.

However, an uppermost end UM2 of the first protective pattern 141-1 may be positioned lower than uppermost ends UM1 of the first pad 120-11a and the second pad 120-12a.

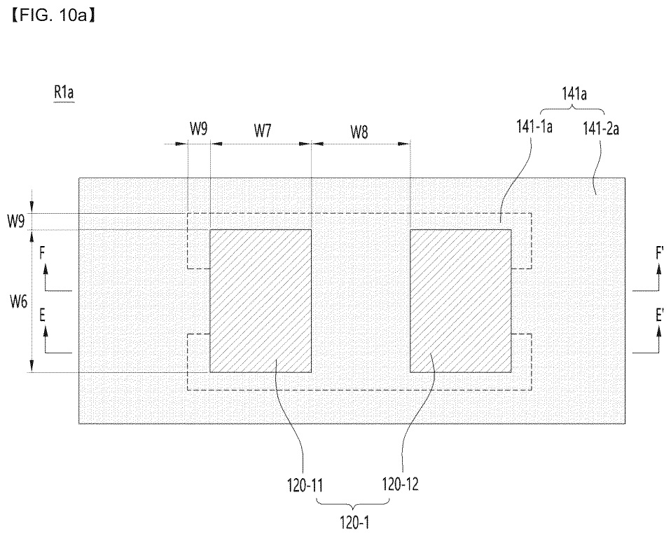

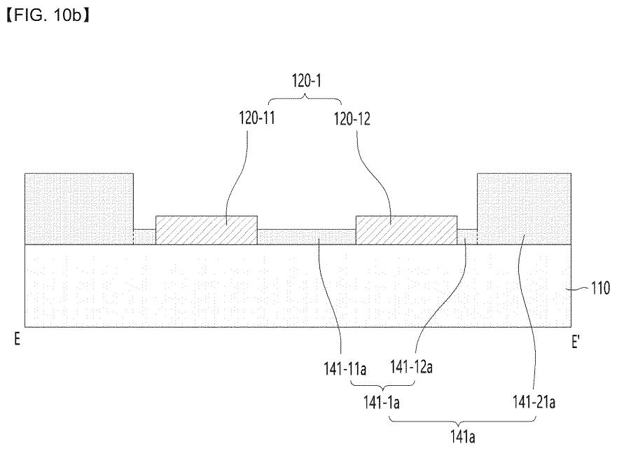

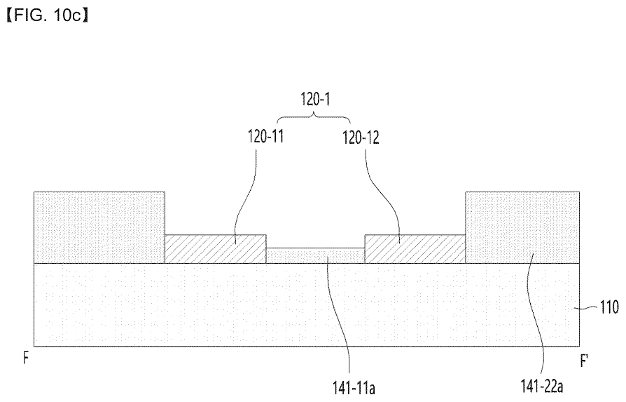

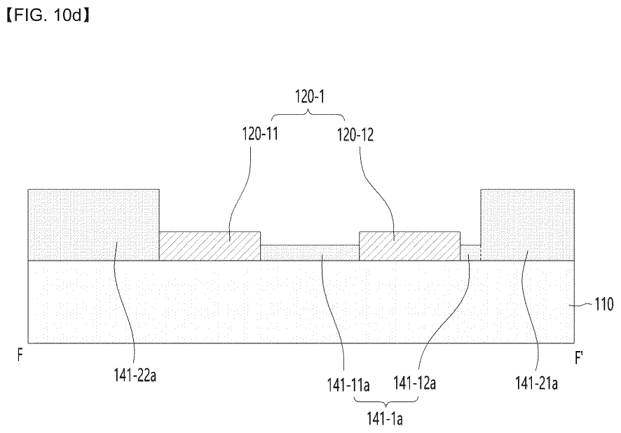

FIG. 10a is a plan view of a first region of a circuit board according to a third embodiment, FIG. 10b is a cross-sectional view taken along a E-E′ direction of FIG. 10a, FIG. 10c is a cross-sectional view taken along a F-F′ direction of FIG. 10a, and FIG. 10d is a modified example of a structure of FIG. 10c.

Hereinafter, a first region of a circuit board according to a third embodiment will be specifically described with reference to FIGS. 10a to 10d.

A first pattern part 120-1 is disposed in the first region Ra of the third embodiment. The first pattern part 120-1 includes a first-first pad 120-11 and a first-second pad 120-12.

A protective portion 141a of a protective layer 140 is disposed the first region R1a.

The protective portion 141a may have different heights depending on a location. Preferably, the protective portion 141a does not contact the upper surface of the first pattern part 120-1 but contacts at least a part of a side surface of the first pattern part 120-1. Here, a fact that the protection part 141 is in contact with at least a portion of the side surface of the first pattern part 120-1 means that at least a part of the side surface of the first pattern part 120-1 is not in contact with the first protective layer 140.

The protective portion 141a includes a first protective pattern 141-1a adjacent to the first pattern part 120-1 in the first region R1a and a second protective pattern 141-2a other than the first protective pattern 141-1a.

For example, the first protective pattern 141-1a may be disposed on at least a part of a peripheral region of the side surfaces of the first-first pad 120-11 and the first-second pad 120-12. At this time, the first protective pattern 141-1 of the previous embodiment is disposed to completely surround the peripheral region of the first pad 120-11 and the second pad 120-12. The first protective pattern 141-1 of the previous embodiment is disposed to surround the peripheral region of the first pad 120-11 and the second pad 120-12 in a closed loop shape.

Unlike this, the first protective pattern 141-1a of the third embodiment may be disposed on at least a part of the peripheral region of the side surfaces of the first-first pad 120-11 and the first-second pad 120-12. That is, the first protective pattern 141-1a may not be disposed in at least some regions around the first pad 120-11 and the second pad 120-12. For example, the first protective pattern 141-1a is disposed to surround the peripheral region the first pad 120-11 and the second pad 120-12 in a closed loop shape.

That is, as in FIG. 10b, the first protective pattern 141-1a includes a first portion 141-11a disposed between the first-first pad 120-11 and the first-second pad 120-12. In addition, the first protective pattern 141-1a includes a second portion 141-12a disposed to surround the side surface of the first-first pad 120-11, the side surface of the first-second pad 120-12, and the side surface of the first portion 141-11a. The second portion 141-12a may not contact at least a portion of the side surface of the first-first pad 120-11 and the side surface of the first-second pad 120-12.

Meanwhile, the second protective pattern 141-2a is disposed around the first protective pattern 141-1a. The second protective pattern 141-2a may have a thickness greater than that of the first protective pattern 141-1a. In addition, the second protective pattern 141-2a may have a thickness greater than that of the first pattern part 120-1a.

The second protective pattern 141-2a is disposed to surround the first protective pattern 141-1a.

In addition, at least a portion of the second protective pattern 141-2a can be in direct contact with the side surface of the first-first pad 120-11 and the side surface of the first-second pad 120-12.

For example, the first-first pad 120-11 includes a plurality of side surfaces. The plurality of side surfaces of the first-first pad 120-11 include a first-first side surface facing the side surface of the first-second pad 120-12 and a first-second side surface opposite to the first-first side surface. And, the second protective pattern 141-2a can be in direct contact with at least a portion of the first-second side surface of the first-first pad 120-11.

In addition, the first-second pad 120-12 includes a plurality of side surfaces. The plurality of side surfaces of the first-second pad 120-12 include a second-first side surface facing the first-first side surface of the first-first pad 120-11 and a second-second side surface opposite the second-first side surface. And, the second protective pattern 141-2a can directly contact at least a part of the second-second side surface of the first-second pad 120-12.

Accordingly, the embodiment can prevent the adhesive member from coming off to an outside of the first-first pad 120-11 and the first-second pad 120-12 by using the second protective pattern 141-2a, thereby improving reliability. However, although the second protective pattern 141-2a is in direct contact with a part of the side surface of the first-first pad 120-11 and the first-second pad 120-12, in this structure, when the first semiconductor device is mounted on the first-first pad 120-11 and the first-second pad 120-12, the second protective pattern 141-2a has a structure that does not overlap with the first semiconductor device in the thickness direction.

Meanwhile, as illustrated in FIG. 10d, the second protective pattern 141-2a may be in contact with one side surface of the first-first pad 120-11 and the first-second pad 120-12 while not being in contact with the other side surface.

That is, the second protective pattern 141-2a may include a first portion 141-22a that is in direct contact with at least a part of the first-second side surface of the first-first pad 120-11.

In addition, the second protective pattern 141-2a may include a second portion 141-21a disposed around the first protective pattern 141-1a without contacting the entire side surface of the first-second pad 120-12.

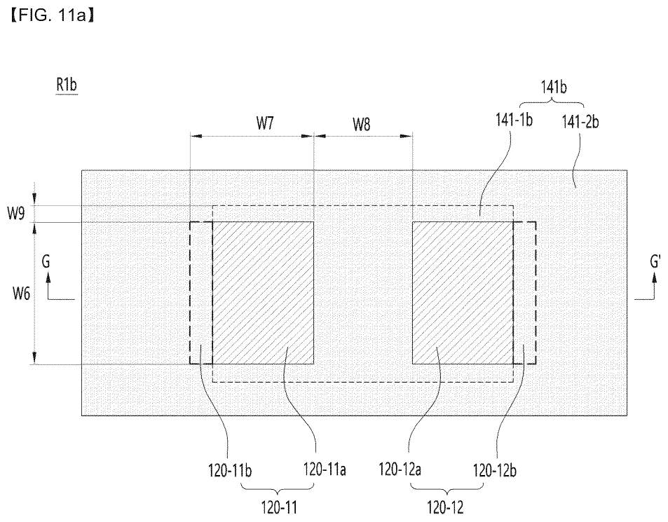

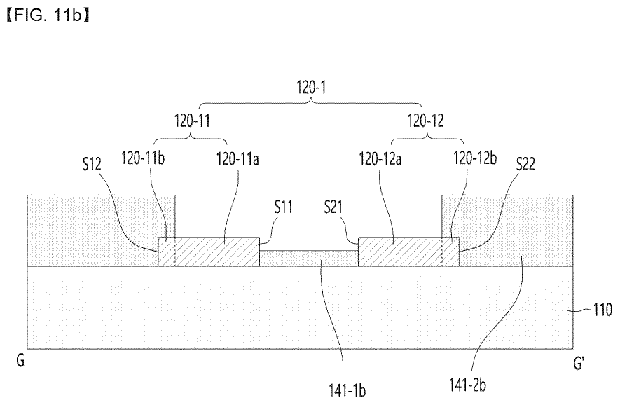

FIG. 11a is a plan view of a first region of a circuit board according to a fourth embodiment, and FIG. 11b is a cross-sectional view taken along a G-G′ direction of FIG. 10a.

Hereinafter, a first region of a circuit board according to a fourth embodiment will be specifically described with reference to FIGS. 11a and 11b.

A first pattern part 120-1 is disposed in a first region R1b of a fourth embodiment. The first pattern part 120-1 includes a first-first pad 120-11 and a first-second pad 120-12.

A protective portion 141b of a protective layer 140 is arranged in the first region R1b.

The protective portion 141b may have different heights depending on the location. Preferably, the protective portion 141b includes a first protective pattern 141-1b adjacent to the first pattern part 120-1 in the first region R1b, and a second protective pattern 141-2b other than the first protective pattern 141-1b.

For example, the first protective pattern 141-1b may be disposed on at least a part of a peripheral region of the side surface of the first-first pad 120-11 and the first-second pad 120-12. At this time, the first protective pattern 141-1 of the previous embodiment is disposed to completely surround the peripheral region of the first pad 120-11 and the second pad 120-12. The first protective pattern 141-1 of the previous embodiment is disposed to surround the peripheral region of the first pad 120-11 and the second pad 120-12 in a closed loop shape.

Unlike this, the first protective pattern 141-1b of the fourth embodiment may be disposed on at least a part of the peripheral region of the side surface of the first-first pad 120-11 and the first-second pad 120-12. That is, the first protective pattern 141-1b may not be disposed on at least a part of the peripheral region of the first pad 120-11 and the second pad 120-12. For example, the first protective pattern 141-1b may be disposed to surround the peripheral region n of the first pad 120-11 and the second pad 120-12 in a closed loop shape.

That is, as shown in FIG. 11a and FIG. 11b, the first protective pattern 141-1b is disposed between the first-first pad 120-11 and the first-second pad 120-12.

In addition, the first protective pattern 141-1b can contact at least a part of the side surface of the first-first pad 120-11 and the side surface of the first-second pad 120-12.

Meanwhile, the second protective pattern 141-2b may have a thickness greater than that of the first protective pattern 141-1b. In addition, the second protective pattern 141-2b may have a thickness greater than that of the first pattern part 120-1b.

The second protective pattern 141-2b is disposed to surround the first protective pattern 141-1b.

In addition, at least a portion of the second protective pattern 141-2b may directly contact the upper surface and side surface of the first-first pad 120-11 and the upper surface and side surface of the first-second pad 120-12.

For example, the first-first pad 120-11 includes a plurality of side surfaces. The plurality of side surfaces of the first-first pad 120-11 include a first-first side surface facing a side surface of the first-second pad 120-12, and a first-second side surface S12 opposite the first-first side surface S11. In addition, the second protective pattern 141-2b may contact the first-second side surface S12 of the first-first pad 120-11 and a portion of the upper surface of the first-first pad 120-11 adjacent to the first-second side surface S12.

In addition, the first-second pad 120-12 includes a plurality of side surfaces. The plurality of side surfaces of the first-second pad 120-12 include a second-first side surface S21 facing the first-first side surface S11 of the first-first pad 120-11, and a second-second side surface S22 opposite the second-first side surface S21. In addition, the second protective pattern 141-2b can contact the second-second side surface S22 of the first-second pad 120-12 and a part of the upper surface of the first-second pad 120-12 adjacent to the second-second side surface S22.

Accordingly, the embodiment can prevent the adhesive member from coming off to the outside of the first-first pad 120-11 and the first-second pad 120-12 by using the second protective pattern 141-2b, thereby improving reliability. However, although the second protective pattern 141-2b is in direct contact with a portion of the upper surface and side surface of the first-first pad 120-11 and the first-second pad 120-12, in this structure, when the first semiconductor device is mounted on the first-first pad 120-11 and the first-second pad 120-12, the second protective pattern 141-2b has a structure that does not overlap with the first semiconductor device in the thickness direction.

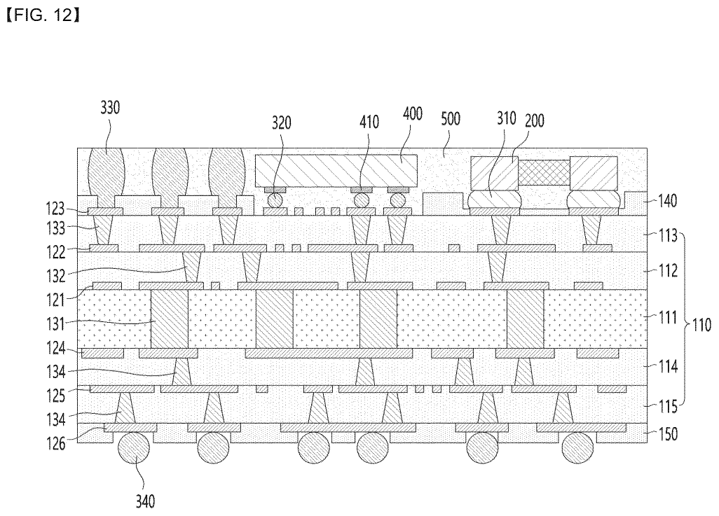

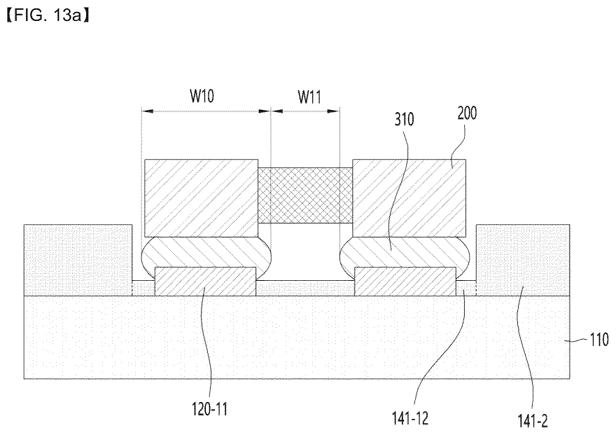

FIG. 12 is a cross-sectional view showing a semiconductor package according to an embodiment, and FIG. 13a is an enlarged view of a first semiconductor device arrangement region of FIG. 12 according to a first embodiment.

The semiconductor package of the embodiment may have a structure in which a semiconductor device is mounted on at least one circuit board as described above.

For example, the semiconductor package may include a first connection part 310 disposed on a first pattern part 121 of a circuit layer 120.

The first connection part 310 may include a spherical shape. For example, a cross-section of the first connection part 310 may include a circular shape or a semicircular shape. For example, a cross-section of the first connection part 310 may include a partially or entirely rounded shape. The cross-section shape of the first connection part 310 may be flat at one side and curved at the other side. The first connection part 310 may be a solder ball, but is not limited thereto.

Alternatively, the first connection part 310 may have a hexahedral shape. For example, the cross-section of the first connection part 310 may include a square shape. The cross-section of the first connection part 310 may include a rectangle or a square.

A first semiconductor device 200 may be mounted on the first connection part 310. The first semiconductor device 200 may be a passive chip. For example, the first semiconductor device 200 may be a multi-layered ceramic capacitor, but is not limited thereto. Meanwhile, although the drawing illustrates that one first semiconductor device 200 is disposed in the semiconductor package, a plurality of first semiconductor devices may be disposed in the first region of the embodiment.

In addition, the semiconductor package includes a second connection part 320 disposed on the second pattern part 122 of the circuit layer 120.

In addition, a second semiconductor device 400 is disposed on the second connection part 320. The second chip 420 may be a processor chip. For example, the second semiconductor device 400 may be an application processor (AP) chip of any one of a central processor (e.g., a CPU), a graphic processor (e.g., a GPU), a digital signal processor, an encryption processor, a microprocessor, and a microcontroller.

At this time, a terminal 425 may be included on a lower surface of the second semiconductor device 400, and the terminal 425 may be electrically connected to the second pattern part 120-2 of the circuit board through the second connection part 320.

Meanwhile, the semiconductor package of the embodiment may have a plurality of second semiconductor devices disposed on one circuit board at a predetermined distance. For example, the second semiconductor device may include a second-first semiconductor device and a second-second semiconductor device that are separated from each other.

In addition, the second-first semiconductor device and the second-second semiconductor device may be different types of application processor (AP) chips.

Meanwhile, the second-first semiconductor device and the second-second semiconductor device may be separated from each other at a predetermined distance on the circuit board. For example, the distance between the second-first semiconductor device and the second-second semiconductor device may be 150 μm or less. For example, the distance between the second-first semiconductor device and the second-second semiconductor device may be 120 μm or less. For example, the distance between the second-first semiconductor device and the second-second semiconductor device may be 100 μm or less.

Preferably, for example, the distance between the second-first semiconductor device and the second-second semiconductor device may have a range of 60 μm to 150 μm. For example, the distance between the second-first semiconductor device and the second-second semiconductor device may have a range of 70 μm to 120 μm. For example, the distance between the second-first semiconductor device and the second-second semiconductor device may have a range of 80 μm to 110 μm. For example, if the spacing between the second-first semiconductor device and the second-second semiconductor device is less than 60 μm, a problem may occur in the operational reliability of the second-first semiconductor device and the second-second semiconductor device due to interference between the second-first semiconductor device and the second-second semiconductor device. For example, if the distance between the second-first semiconductor device and the second-second semiconductor device is greater than 150 μm, signal transmission loss may increase as the distance between the second-first semiconductor device and the second-second semiconductor device increases.

In addition, the semiconductor package further includes a third connection part 330 disposed in the third region R3. The third connection part 330 may be disposed on the third pattern part 120-3 of the circuit layer 120 of the embodiment. The third connection part 330 may be a connection part for connection with a separate external substrate (e.g., a memory substrate).

In addition, the semiconductor package may include a molding layer 500. The molding layer 500 may be disposed to cover the first semiconductor device 200) and the second chip 400. For example, the molding layer 500 may be an EMC (Epoxy Mold Compound) formed to protect the mounted first semiconductor device 200 and the second chip 400, but is not limited thereto. The molding layer 500 may include an opening exposing an upper surface of the third connection part 330. For example, the upper surface of the third connection part 330 may not be in contact with the molding layer 500. The third connection part 330 may be a solder ball, or alternatively, may be a post bump.

At this time, the molding layer 500 may have a low permittivity to enhance the heat dissipation characteristics. For example, the permittivity (Dk) of the molding layer 500 may be 0.2 to 10. For example, the permittivity (Dk) of the molding layer 500 may be 0.5 to 8. For example, the permittivity (Dk) of the molding layer 500 may be 0.8 to 5. Accordingly, in the embodiment, the molding layer 500 is made to have a low permittivity, thereby enhancing the heat dissipation characteristics for heat generated from the first semiconductor device 200 and the second chip 400.

Meanwhile, a package substrate may include a fourth connection part 340 disposed at a lowest side of the circuit board. The fourth connection part 340 may be for bonding between the semiconductor package and the external substrate (for example, the main board of the external device).

Meanwhile, as shown in FIG. 13a, in the embodiment, the first connection part 310 is disposed on the first-first pad 120-11 and the first-second pad 120-12 of the first pattern part 120-1.

At this time, the first connection part 310 comes into contact with at least a part of the side surface of the first-first pad 120-11 and the first-second pad 120-12. And, the first connection part 310 does not come into contact with at least a part of the side surface of the first-first pad 120-11 and the first-second pad 120-12. For example, the first connection part 310 may come into contact with the upper surface of the first protective pattern 141-1 of the protective layer 140.

Accordingly, a lowermost end of the first connection part 310 in the embodiment may be positioned higher than the upper surface of the insulating layer 110. In addition, a lowermost end of the first connection part 310 of the embodiment is positioned higher than the lower surface of the first pattern part 120-1 and lower than the upper surface of the first pattern part 120-1.

Therefore, in the embodiment, a width W10 of the first connection part 310 can be reduced compared to the comparative example. For example, the width W10 of the first connection part 310 can be 125% or less of the width of the first-first pad 120-11 and the first-second pad 120-12 in the second horizontal direction. For example, the width W10 of the first connection part 310 can be 120% or less of the width of the first-first pad 120-11 and the first-second pad 120-12 in the second horizontal direction. Accordingly, in the embodiment, a spacing W11 between the first connection part disposed on the first-first pad 120-11 and the first connection part disposed on the first-second pad 120-12 can be increased compared to the comparative example.

For example, when the spacing between the first-first pad and the first- second pad of the comparative example and the embodiment is the same, the spacing W11 between the plurality of first connection parts of the embodiment can be 90% or less, 80% or less, or further 70% or less of the spacing between the plurality of first connection parts of the comparative example.

Meanwhile, the first connection part 310 in FIG. 13A has a shape of a circular solder ball.

Differently, as shown in FIG. 13B, the first connection part 310B of the second embodiment can have a solder fillet shape. For example, the first connection part 310B of the second embodiment can be a paste.

In addition, the first connection part 310B may form a solder fillet that extends to the side surface of the first semiconductor device 200B as the first semiconductor device 200B is seated while being disposed on the first-first pad 120-11 and the first-second pad 120-12.

In addition, when the first connection part 310B of the second embodiment is applied and the first semiconductor device 200B is mounted, a distance (for example, the distance in the vertical direction or the thickness direction) between the first pattern part 120-1 and the first semiconductor device 200B can be further reduced compared to the first embodiment. At this time, when the first connection part 310B of the second embodiment is applied, the first protective pattern 141-1 of the protective layer 140 between the first-first pad 120-11 and the first-second pad 120-12 can be omitted. However, even when the first connection part 310B of the second embodiment is applied, a problem may occur in which the first connection part 310B penetrates between the insulating layer and the first pattern part. Furthermore, a circuit short problem may occur in which the first-first pad 120-11 and the first-second pad 120-12 are electrically connected to each other by the first connection part 310B. Accordingly, in the second embodiment, a first protective pattern 141-1 of a protective layer 140 is disposed between the first-first pad 120-11 and the first-second pad 120-12, thereby solving a reliability problem caused by the flow of the first connection part 310B.

The circuit board of the embodiment includes a first region in which a first semiconductor device is arranged.

In addition, the circuit board includes a first-first pad and a first-second pad. The first-first pad and the first-second pad are provided so as to overlap the first semiconductor device in a vertical direction. For example, the first-first pad and the first-second pad are provided in a first region of the circuit board. In addition, the embodiment includes a protective layer. The protective layer includes a first protective pattern disposed between the first-first pad and the first-second pad, and surrounding at least a portion of a side surface of the first-first pad and a side surface of the first-second pad. In addition, the protective layer includes a second protective pattern provided surrounding the first protective pattern.

The first protective pattern contacts at least a portion of a side surface of the first-first pad and the first-second pad without contacting upper surfaces of the first-first pad and the first-second pad. For example, an upper surface of the first protective pattern is positioned lower than the upper surfaces of the first-first pad and the first-second pad. Therefore, the embodiment can reduce a thickness and a width of a contact member to be disposed on the first-first pad and the first-second pad by using the first protective pattern.

For example, a first comparative example has a problem in that a thickness of the contact member increases due to an arrangement of the protective layer, and the second comparative example had a problem in that an degree of expansion of the contact member increased due to an non-arrangement of the protective layer, thereby increasing the width of the contact member.

In contrast, the embodiment can reduce the degree of expansion of the contact member and reduce the width of the contact member by using a combination of the first and second protective patterns. In addition, the embodiment provides only the first protective pattern in a region that vertically overlaps the first semiconductor device. For example, the second protective pattern does not vertically overlap the first semiconductor device. Therefore, the embodiment can prevent a thickness of the contact member from increasing due to a height of the protective layer.

Accordingly, the embodiment can reduce a thickness of the semiconductor package, thereby achieving miniaturization. Furthermore, the embodiment can solve a problem of a circuit short between adjacent contact members by reducing the degree of expansion of the contact member. As a result, the embodiment can improve the electrical reliability and product reliability of the semiconductor package. Furthermore, the embodiment can solve the problem of a circuit short without increasing a spacing between the first-first pad and the first-second pad, thereby improving circuit integration.

In addition, the embodiment can solve a problem of an adhesive member penetrating between an insulating layer and a pad by using the first protective pattern, thereby further improving product reliability.

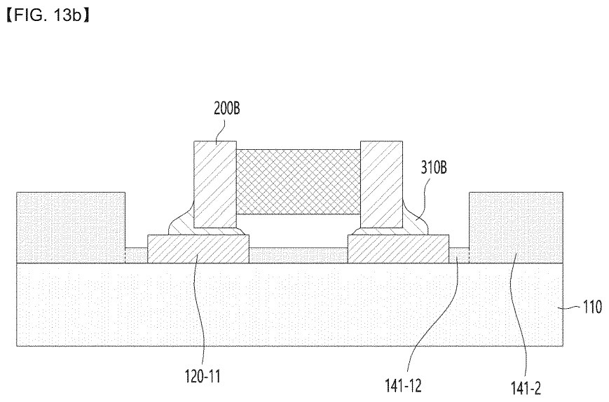

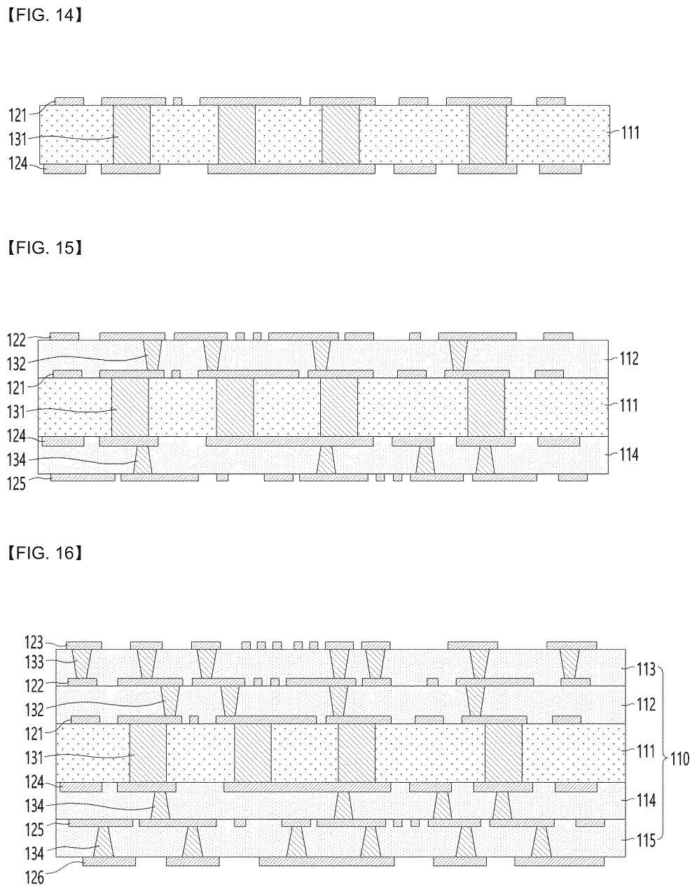

FIGS. 14 to 21 are cross-sectional views showing a process of manufacturing a circuit board according to an embodiment in order of processes.

Referring to FIG. 14, the embodiment prepares a first insulating layer 111 that serves as a basis for manufacturing the circuit board. The first insulating layer 111 may be a core layer, but is not limited thereto.

Next, the embodiment forms a first through electrode 131 that penetrates the first insulating layer 111. And, the embodiment proceeds with a process of forming a first circuit layer 121 on an upper surface of a first insulating layer 111 and forming a fourth circuit layer 124 on a lower surface of the first insulating layer 111 along with the formation of a first through electrode 131.

Next, referring to FIG. 15, the embodiment laminates a second insulating layer 112 on the upper surface of the first insulating layer 111, and laminates a fourth insulating layer 114 on the lower surface of the first insulating layer 111.

Thereafter, the embodiment performs a process of forming a second through electrode 132 and a second circuit layer 122 on the second insulating layer 112. In addition, the embodiment performs a process of forming a fourth through electrode 132 and a fifth circuit layer 125 on the fourth insulating layer 114.

Next, referring to FIG. 16, the embodiment laminates a third insulating layer 113 on the upper surface of the second insulating layer 112, and laminates a fifth insulating layer 115 on the lower surface of the fourth insulating layer 114.

Thereafter, the embodiment performs a process of forming a third through electrode 133 and a third circuit layer 123 on the third insulating layer 113. In addition, the embodiment performs a process of forming a fifth through electrode 135 and a sixth circuit layer 126 on the fifth insulating layer 115.

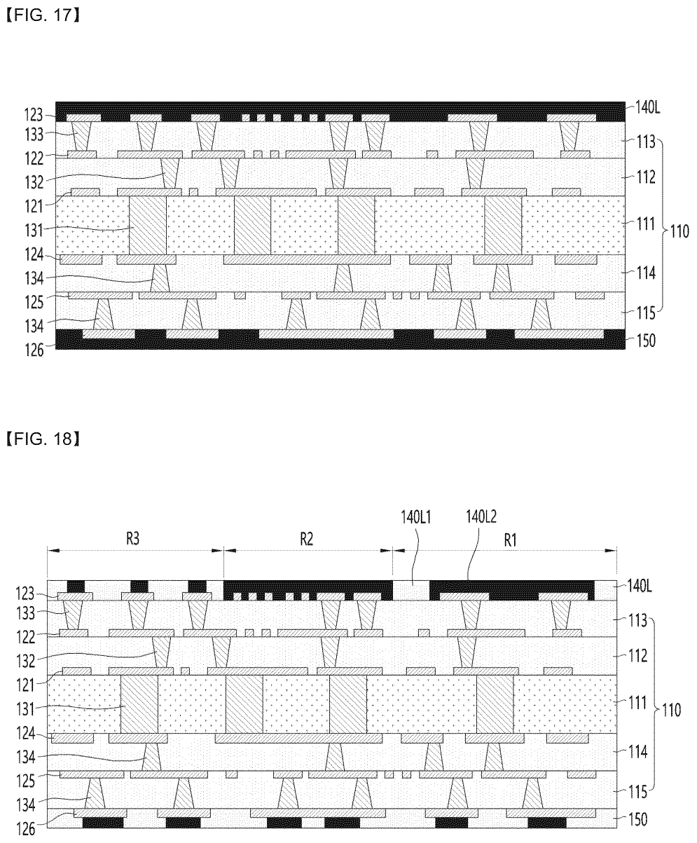

Next, referring to FIG. 17, the embodiment forms a first solder resist layer 140L on the third insulating layer 113, and forms a second solder resist layer 150L under the fifth insulating layer 115. At this time, the first solder resist layer 140L is disposed to entirely cover the third circuit layer 123 on the third insulating layer 113. In addition, the second solder resist layer 150L is disposed to entirely cover the sixth circuit layer 126 under the fifth insulating layer 115.

Next, referring to FIG. 18, the embodiment may perform a process of partially exposing and curing the first solder resist layer 140L and the second solder resist layer 150L, respectively.

Accordingly, the first solder resist layer 140L according to an embodiment may be subjected to differential exposure and curing in each of the first region R1, the second region R2, and the third region R3. Accordingly, the first region R1 may include a cured region 140L1 and an uncured region 140L2. In this case, the cured region 140L1 in the first region R1a does not vertically overlap the third circuit layer 123 disposed in the first region R1a.

Also, the uncured region 140L2 may be only included in the second region R2. Also, the third region R3 may include a cured region 140L1 and an uncured region 140L2.

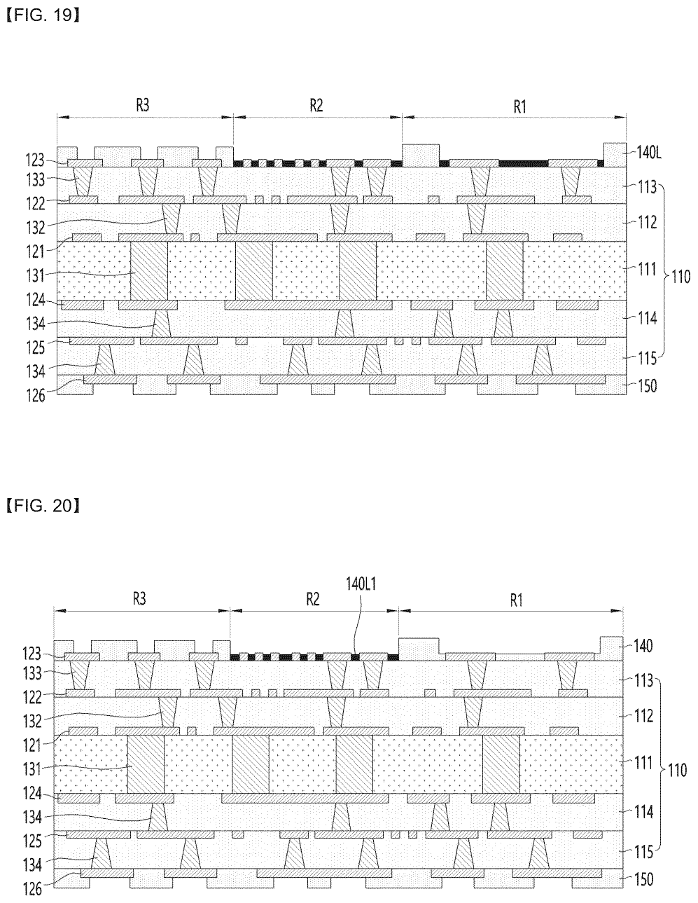

Next, referring to FIG. 19, in the embodiment, a thinning process of developing the uncured region 140L2 may be performed. A height of the uncured region 140L2 may be lowered by the thinning process. In this case, the height of the uncured region 140L2 may be freely adjusted by adjusting a thinning process condition (e.g., a process time).

The thinning process may include a process of thinning the uncured region 140L2 using an organic alkaline compound containing tetramethylammonium hydroxide (TMAH) or trimethyl-2-hydroxyethylammonium hydroxide (choline).

Next, referring to FIG. 20, in the embodiment, a process of curing the uncured region 140L2) of the first region R1 can be performed. In this case, according to the first embodiment, since the protective layer 140 is not disposed in the second region R2, the uncured region 140L2 in the second region R2 may not be cured. However, since the third protective pattern 142 remains in the second region R2 of the second embodiment, a process of curing the uncured region of the second region R2 may be performed.

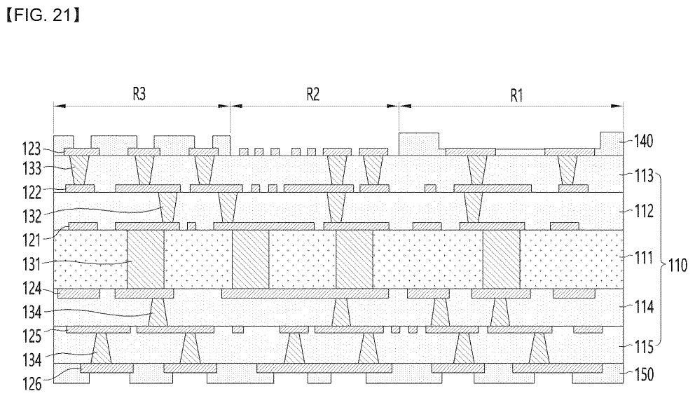

Next, referring to FIG. 21, the embodiment may proceed with a process of thinning the uncured region of the second region R2 to remove all of the protective layer 140 present in the second region R2.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
an insulating layer;
a circuit layer disposed on the insulating layer; and
a protective layer disposed on the insulating layer,
wherein the circuit layer includes a first pad and a second pad spaced apart from each other in a first horizontal direction,
wherein the protective layer includes:
a first protective pattern disposed between the first pad and the second pad and disposed along a side surface of the first pad and a side surface of the second pad; and
a second protective pattern disposed surrounding the first protective pattern,
wherein an upper surface of the first protective pattern is positioned lower than an upper surface of the first pad and an upper surface of the second pad.
wherein an upper surface of the second protective pattern is positioned higher than the upper surfaces of the first pad and the second pad, and
wherein each of the first pad and the second pad has different widths in the first horizontal direction and in a second horizontal direction perpendicular to the first horizontal direction.

2. The circuit board of claim 1, wherein a thickness of the first protective pattern satisfies a range of 40% to 90% of a thickness of at least one of the first pad and the second pad

3. The circuit board of claim 1, wherein a thickness of at least one of the first pad and the second pad satisfies a range of 10 μm to 25 μm, and
wherein a thickness of the first protective pattern satisfies a range of 3 μm to 21 μm.

4. The circuit board of claim 1, wherein a distance between the upper surface of at least one of the first pad and the second pad and the upper surface of the first protective pattern in a vertical direction perpendicular to the first horizontal direction and the second horizontal direction satisfies a range of 3 μm to 10 μm.

5. The circuit board of claim 4, wherein at least one of the upper surfaces of the first pad and the second pad includes a curved surface, and
wherein the distance in the vertical direction is a distance in the vertical direction from an uppermost surface of the at least one of the first pad and the second pad to an uppermost surface of the first protective pattern.

6. The circuit board of claim 3, wherein the thickness of the second protective pattern satisfies a range of 17 μm to 45 μm.

7. The circuit board of claim 1, wherein the width of each of the first pad and the second pad in the second horizontal direction is in a range of 125% to 220% of the width of each of the first pad and the second pad in the first horizontal direction.

8. The circuit board of claim 7, wherein a spacing in the first horizontal direction between the first pad and the second pad satisfies a range of 70% to 120% of the width of each of the first pad and the second pad in the first horizontal direction.

9. The circuit board of claim 1, wherein an inner wall of the second protective pattern is spaced apart from a side surface of at least one of the first pad and the second pad by a spacing of 15 μm to 23 μm.

10. The circuit board of claim 1, wherein the first protective pattern is provided to partially surround the side surfaces of the first pad and the second pad, and
wherein at least a portion of the second protective pattern is in contact with the side surface of the first pad or the side surface of the second pad.

11. The circuit board of claim 1, wherein the first protective pattern and the second protective pattern do not overlap the first pad and the second pad along a vertical direction perpendicular to the first horizontal direction and the second horizontal direction.

12. The circuit board of claim 1, wherein the first pad includes a first side surface facing the second pad in the first horizontal direction, and a second side surface excluding the first side surface,
wherein the second pad includes a third side surface facing the first side surface, and a fourth side surface excluding the third side surface, and
wherein the second protective pattern is in direct contact with at least a portion of the second side surface of the first pad or at least a portion of the fourth side surface of the second pad.

13. The circuit board of claim 1, wherein the circuit layer includes a third pad and a first trace arranged adjacent to the third pad, and
wherein a width of the third pad and the first trace in the first horizontal direction is smaller than the width of the first pad and the second pad in the first horizontal direction.

14. The circuit board of claim 13, wherein the protective layer includes a first through hole overlapping the third pad, the first trace, and a region between the third pad and the first trace along a vertical direction perpendicular to the first horizontal direction and the second horizontal direction.

15. The circuit board of claim 14, wherein a plurality of third pads and a plurality of first traces are arranged within the first through hole.

16. The circuit board of claim 13, wherein the circuit layer further includes a plurality of fourth pads, and
wherein a width of the fourth pad in the first horizontal direction is smaller than the widths of the first pad and the second pad in the first horizontal direction.

17. The circuit board of claim 16, wherein the protective layer further includes a plurality of second through holes overlapping the plurality of fourth pads along a vertical direction perpendicular to the first horizontal direction and the second horizontal direction.

18. The circuit board of claim 17, wherein a width of the second through hole in the first horizontal direction is smaller than a width of the fourth pad in the first horizontal direction, and
wherein at least a portion of the fourth pad overlaps the protective layer along the vertical direction.

19. The circuit board of claim 2, wherein a thickness of at least one of the first pad and the second pad satisfies a range of 10 μm to 25 μm, and
wherein a thickness of the first protective pattern satisfies a range of 3 μm to 21 μm.

20. The circuit board of claim 2, wherein a distance between the upper surface of at least one of the first pad and the second pad and the upper surface of the first protective pattern in a vertical direction perpendicular to the first horizontal direction and the second horizontal direction satisfies a range of 3 μm to 10 μm.
